(19) United States
(12) Patent Application Publication
(10) Pub. No.: US 2017/0309840 A1
(43) Pub. Date: Oct. 26, 2017

(54) HIGH EFFICIENCY DYE SENSITIZED PHOTOELECTROSYNTHESIS CELLS

(71) Applicant: The University of North Carolina at Chapel Hill, Chapel Hill, NC (US)

(72) Inventors: Leila Alibabaei, Carrboro, NC (US); Benjamin D. Sherman, Chapel Hill, NC (US); M. Kyle Brennaman, Durham, NC (US); Thomas J. Meyer, Chapel Hill, NC (US)

(73) Assignee: The University of North Carolina at Chapel Hill, Chapel Hill, NC (US)

(21) Appl. No.: 15/517,233

(22) PCT Filed: Nov. 6, 2015
(86) PCT No.: PCT/US15/59412

§ 371 Date: Apr. 6, 2017

Related U.S. Application Data
(60) Provisional application No. 62/075,908, filed on Nov. 6, 2014.

(51) Int. Cl. H01L 51/00; H01G 9/20; C25B 11/04; C25B 1/00; C01B 3/04

(52) U.S. Cl. CPC H01L 51/0086; H01L 51/009; H01G 9/2059; C01B 3/042; C25B 11/04; C25B 1/003; H01G 9/2031

(57) ABSTRACT

Electrodes useful in dye sensitized photoelectrosynthesis cells provide a coreshell nanoparticle having a chromophore and a catalyst, or a chromophore-catalyst assembly, linked to the shell material. Optionally, an overlayer stabilizes the chromophore or chromophore-catalyst assembly on the shell material. In some embodiments, the core material comprises tin oxide; the shell material comprises titanium dioxide; the chromophore-catalyst assembly includes [(PO₃H₂)₂bpy)₂Ru(4-Mebpy-4′-bimpy)Ru(tpy) (OH₂)]⁴⁺, and the overlayer comprises aluminum oxide or titanium dioxide.

### CROSS REFERENCE TO RELATED APPLICATIONS

This international application claims benefit of priority to U.S. Provisional Patent Application Ser. No. 62/075,908, entitled, “HIGH EFFICIENCY DYE SENSITIZED PHOTOELECTROSYNTHESIS CELLS,” filed on Nov. 6, 2014, the disclosure of which is incorporated herein by reference in its entirety.

### STATEMENT REGARDING FEDERALLY SPONSORED RESEARCH OR DEVELOPMENT

This invention was made with government support under Grant No. DE-SC0001011 awarded by the U.S. Department of Energy. The government has certain rights in the invention.

### FIELD OF INVENTION

This invention relates to methods and devices for photochemistry, such as, for example, dye sensitized photoelectrosynthesis cells. In some cases, visible light can be used to efficiently split water into hydrogen and oxygen.

### BACKGROUND OF THE INVENTION

Although promising, significant challenges remain in the search for successful strategies for artificial photosynthesis based on water splitting into oxygen and hydrogen or H₂O reduction of CO₂ to reduced carbon fuels. In a Dye Sensitized Photoelectrosynthesis Cell (DSPEC), a wide band gap, nanoparticle oxide film, typically TiO₂, is derivatized with a surface-bound molecular assembly or assemblies for light absorption and catalysis or with a surface co-loading approach. The efficiency of a photoanode-based DSPEC device depends on the interface and the dynamics of a series of competing processes—solar insolation, injection, back electron transfer, intra-assembly electron transfer, electron migration through the oxide film, and water oxidation. A major limiting factor in DSPEC applications arises from the 4e⁻/4H⁺ nature of the water oxidation half reaction, 2H₂O-4e⁻-4H⁺→O₂, with the buildup of multiple oxidative equivalents in competition with back electron transfer to the oxidized assembly.

### SUMMARY OF THE INVENTION

Certain embodiments of the present invention provide electrodes comprising at least one core-shell nanoparticle, comprising a core material at least partially encompassed by a shell material. In further instances, those electrodes can further comprise at least one chromophore and at least one catalyst, or at least one chromophore-catalyst assembly. The chromophore is adapted to absorb visible light, and the catalyst is in electron-transfer communication with the chromophore and is adapted to perform at least one chemical reaction. The at least one chromophore or at least one chromophore-catalyst assembly comprises at least one linking moiety attaching the chromophore or chromophore-catalyst assembly to the shell material. Additional instances provide at least one overlayer material stabilizing the chromophore or chromophore-catalyst assembly on the shell material.

Some embodiments of the present invention relate to electrodes comprising:
at least one core-shell nanoparticle, comprising:

a core material at least partially encompassed by a shell material; at least one chromophore-catalyst assembly, comprising:

a chromophore adapted to absorb visible light;
a catalyst in electron-transfer communication with the chromophore, and adapted to perform at least one chemical reaction; and
at least one linking moiety attaching the chromophore-catalyst assembly to the shell material; and
   at least one overlayer material stabilizing the chromophore-catalyst assembly on the shell material.

Further embodiments relate to photoelectrosynthesis cells, comprising: a counter electrode; an electrolyte; and
an electrode as described above.

Other embodiments of the present invention provide methods of splitting water into hydrogen and oxygen, comprising:
supplying a photoelectrosynthesis cell as described above;
connecting the electrode with the counter electrode via an external electrical circuit;
contacting the electrode and counter electrode with an aqueous electrolyte;
and illuminating the electrode with visible light, thereby splitting water.

Additional embodiments relate to methods of reducing carbon dioxide, comprising:
supplying a photoelectrosynthesis cell as described above;
connecting the electrode with the counter electrode via an external electrical circuit;
contacting the electrode and counter electrode with an electrolyte;
contacting the electrode with carbon dioxide;
and illuminating the electrode with visible light, thereby reducing the carbon dioxide.

While the disclosure provides certain specific embodiments, the invention is not limited to those embodiments. A person of ordinary skill will appreciate from the description herein that modifications can be made to the described embodiments and therefore that the specification is broader in scope than the described embodiments. All examples are therefore non-limiting.

### BRIEF DESCRIPTION OF THE DRAWINGS

The figures are not necessarily to scale, and should not be construed as limiting. Some details may be exaggerated to aid comprehension.

FIG. 1 provides a structure of a chromophore-catalyst assembly.

FIG. 2 provides a transmission electron micrograph (TEM) depicting an electrode comprising core/shell nanostructure from 75 ALD cycles of TiO₂ deposited onto SnO₂ nanoparticle films on FTO glass (FTO|SnO₂/TiO₂(4.5 nm)|).

FIG. 3 schematically depicts an embodiment of the invention comprising SnO₂/TiO₂ core-shell nanoparticles on a FTO conductive substrate, further comprising a chromophore-catalyst assembly on the TiO₂ shell material.

FIG. 4 schematically depicts a further embodiment comprising SnO₂/TiO₂ core-shell nanoparticles on a FTO conductive substrate, further comprising a chromophore-catalyst assembly and an overlayer material.

FIG. 5 presents photocurrent comparisons between SnO₂ and nanoITO core/TiO₂ photoanodes, FTO|SnO₂/TiO₂|—[Ruₐ^{II}—Ru_{b}^{II}—OH₂]⁴⁺ (thin solid line) and FTO|nanoITO/TiO₂|—[Ruₐ^{II}—Ru_{b}^{II}—OH₂]⁴⁺ (thick grey line), with 50 cycle ALD TiO₂ shells (3.3 nm) derivatized with the chromophore-catalyst assembly of FIGS. 1, 3, and 4, with a Pt counter electrode and 200 mV (vs. Ag/AgCl) applied bias at pH 4.6 in 0.5 M LiClO₄ with 20 mM acetate/acetic acid buffer. The thick solid line trace shows the impact of a 10 cycle TiO₂ overlayer on the photocurrent output of the SnO₂ core/shell electrode.

FIG. 6 provides photocurrent-time curves for FTO|SnO₂/TiO₂(6.6 nm)|-[Ruₐ^{II}—Ru_{b}^{II}—OH₂]⁴⁺ with 10 cycles of an added TiO₂ overlayer (see FIG. 4): 400 mV applied bias vs. Ag/AgCl in 0.5 M LiClO₄ 20 mM in acetic acid/acetate buffer at pH 4.6 (thick solid line) and in a 0.1 M H₂PO₄⁻/HPO₄²⁻ buffer at pH 7 with the ionic strength adjusted to 0.5 M with NaClO₄ (thick grey line).

FIG. 7 provides photocurrent versus time trace depicting photoelectrochemical water splitting by FTO|SnO₂/TiO₂(6.6 nm)|-[Ruₐ^{II}—Ru_{b}^{II}—OH₂]⁴⁺(0.3 nmAl₂O₃) (see FIG. 4) with a 600 mV applied bias in a 0.1 M H₂PO₄⁻/HPO₄²⁻ buffer at pH 7 at room temperature. The bias was applied across the working and counter electrodes (the experiment was performed in a two electrode configuration with the counter and reference leads both connected to the Pt counter electrode). The ionic strength was adjusted to 0.5 M with NaClO₄. Illumination was accomplished with a 455 nm LED at 46.2 mW/cm².

FIG. 8 provides H₂ and O₂ evolution time traces recorded in concert with the photocurrent trace of FIG. 7.

FIG. 9 provides photocurrent comparisons for a FTO|SnO₂/TiO₂(6.6 nm)|-[Ruₐ^{II}—Ru_{b}^{II}—OH₂]⁴⁺ photoanode in pH 4.6 acetate (20 mM) and pH 7 phosphate (0.1 M) buffers illustrating the effect of ALD overlayers of TiO₂ and Al₂O₃.

FIG. 10 depicts linear voltammetry measurements in pH 4.6, 0.5 M LiClO₄, 20 mM acetic acid/acetate buffer recorded with a FTO|SnO₂/TiO₂(4.5 nm)|-[Ruₐ^{II}—Ru_{b}^{II}—OH₂]⁴⁺ photoanode with no ALD overlayer (thin solid line), 10 cycles TiO₂ ALD overlayer (thick solid line), and 20 cycles of TiO₂ ALD (thick grey line). Traces in light taken under continuous illumination at 445 nm (10 mW/cm², FWHM 20 nm).

FIG. 11 presents a photograph of one embodiment of a DSPEC device.

FIG. 12 depicts schematically the DSPEC of FIG. 11.

### DETAILED DESCRIPTION

As required, detailed embodiments of the present invention are disclosed herein; however, it is to be understood that the disclosed embodiments are merely exemplary of the invention that may be embodied in various forms. The figures are not necessarily to scale, and some features may be exaggerated to show details of particular components. Therefore, specific structural and functional details disclosed herein are not to be interpreted as limiting, but merely as a basis for the claims and as a representative basis for teaching one skilled in the art to variously employ the present invention.

Unless defined otherwise, all technical and scientific terms used herein have the same meaning as is commonly understood by one of ordinary skill in the art to which this disclosure belongs. In the event that there is a plurality of definitions for a term herein, those in this section prevail unless stated otherwise.

Where ever the phrase “for example,” “such as,” “including” and the like are used herein, the phrase “and without limitation” is understood to follow unless explicitly stated otherwise. Similarly “an example,” “exemplary” and the like are understood to be non-limiting.

The term “substantially” allows for deviations from the descriptor that don't negatively impact the intended purpose. Descriptive terms are understood to be modified by the term “substantially” even if the word “substantially” is not explicitly recited.

The term “about” when used in connection with a numerical value refers to the actual given value, and to the approximation to such given value that would reasonably be inferred by one of ordinary skill in the art, including approximations due to the experimental and or measurement conditions for such given value.

The terms “comprising” and “including” and “having” and “involving” (and similarly “comprises”, “includes,” “has,” and “involves”) and the like are used interchangeably and have the same meaning. Specifically, each of the terms is defined consistent with the common United States patent law definition of “comprising” and is therefore interpreted to be an open term meaning “at least the following,” and is also interpreted not to exclude additional features, limitations, aspects, etc. Thus, for example, “a device having components a, b, and c” means that the device includes at least components a, b and c. Similarly, the phrase: “a method involving steps a, b, and c” means that the method includes at least steps a, b, and c.

Unless the context clearly requires otherwise, throughout the description and the claims, the words “comprise”, “comprising”, and the like are to be construed in an inclusive sense as opposed to an exclusive or exhaustive sense; that is to say, in the sense of “including, but not limited to”.

Any discussion of the prior art throughout the specification should in no way be considered as an admission that such prior art is widely known or forms part of common general knowledge in the field. Nor should such discussion be misconstrued as an admission that discussed information is part of the “prior art.”

It is an object of the present invention to overcome or ameliorate at least one of the disadvantages of the prior art, or to provide a useful alternative.

As mentioned above, certain instances of the present invention relate to electrodes. Any suitable electrically-conductive substrate can be used for electrodes. Metals, ceramics, or glass coated with a thin layer of a conductive metal oxide may be mentioned. In some cases, the conductive metal oxide comprises tin-doped indium oxide (ITO), fluorine-doped tin oxide (FTO), antimony tin oxide (ATO), gallium zinc oxide (GZO), indium zinc oxide (IZO), copper aluminum oxide, fluorine-doped zinc oxide, aluminum zinc oxide (AZO), or a combination of two or more thereof. Optionally, the conductive metal oxide is transparent, transmitting at least 50% of the visible light spectrum. Electrodes can have any suitable dimensions and geometric shapes. In some cases, the electrode is substantially planar.

Those electrodes may comprise at least one core-shell nanoparticle, comprising a core material at least partially encompassed by a shell material. The core-shell nanoparticles on an electrode can contain the same materials, or a mixture of core-shell nanoparticles having different materials can appear on an electrode. Any suitable core material may be used. In some cases, the core material is a semiconductor metal oxide. In other cases, the core material comprises SnO₂. In still other cases, the core material comprises tin-doped indium oxide (ITO), fluorine doped tin oxide (FTO), antimony tin oxide (ATO), gallium zinc oxide (GZO), indium zinc oxide (IZO), copper aluminum oxide (CAO), fluorine doped zinc oxide (FZO), aluminum zinc oxide (AZO), SnO₂, ZrO₂, TiO₂, Al₂O₃, SiO₂, or a combination of two or more thereof. It may be said that the core material is in electronic-transfer communication with an electrically-conductive substrate. This allows electron transfer between the core material to the electrically-conductive substrate, thereby allowing electrical current to flow through the electrode.

Any suitable shell material can be used. For example, the overlayer material may comprise Al₂O₃, TiO₂, ZnO, and combinations thereof. It can be said that some cases allow the overlayer material to comprise a semiconducting or insulating metal oxide material, while the core material comprises a conductive or more conductive material. Certain instances provide both the core material and the shell material are semiconductors. For electron transfer to occur, in some cases, the core material has a core material conduction band potential that is more positive than the shell material's conduction band potential. For example, the core material conduction band potential can be at least about 0.2 V, at least about 0.3 V, or at least about 0.4 V more positive than the shell material's conduction band potential.

In some cases, the shell material partially encompasses the core material. In other cases, the shell material completely encompasses the core material. It may be possible to determine a thickness of shell material on the core material. This determination can be done in any suitable fashion. For example, a planar substrate may be subjected to the same process for forming the shell material as the core material, and the thickness of the shell material on the planar substrate can be determined.

The core-shell nanoparticles of the present invention can be any suitable size. The core material can form nanoparticles of dimension up to about 1 pm, in some cases, and then the shell material can be formed or deposited thereon. Certain instances provide a core material in the form of nanoparticles having a dimension of at least about 1 nm, at least about 10 nm, at least about 20 nm, at least about 50 nm, at least about 100 nm, at least about 250 nm, at least about 500 nm, or at least about 800 nm. In other cases, the core material nanoparticles can be no greater than about 5 nm, no greater than about 15 nm, no greater than about 25 nm, no greater than about 75 nm, no greater than about 150 nm, no greater than about 300 nm, no greater than about 600 nm, no greater than about 900 nm, or no greater than about 1 μm, in other instances.

The thickness of the shell material on the core material can be any suitable thickness. In some cases, the thickness is determined by balancing the need for efficient forward electron transfer from a chromophore in the excited state with the need to inhibit back electron transfer from the nanoparticles to the oxidized chromophore. The thickness of the shell material can be at least about 1 nm, at least about 2 nm, at least about 3 nm, at least about 5 nm, at least about 10 nm, at least about 15 nm, at least about 20 nm, or at least about 50 nm, in certain instances. In other cases, the thickness of the shell material can be no greater than about 1 nm, no greater than about 2 nm, no greater than about 3 nm, no greater than about 5 nm, no greater than about 10 nm, no greater than about 15 nm, no greater than about 20 nm, or no greater than about 50 nm, in other instances.

The thickness of a layer of core-shell nanoparticles on a substrate can be any suitable thickness. In some cases, the thickness of the layer of core-shell nanoparticles can be no more than about 0.5 μm, no more than about 1 μm, no more than about 2 μm, no more than about 5 μm, no more than about 10 μm, no more than about 20 μm, no more than about 50 μm, no more than about 100 μm, or no more than about 1000 μm. In other cases, the thickness of the layer of core-shell nanoparticles is at least about 0.5 μm, at least about 1 μm, at least about 2 μm, at least about 5 μm, at least about 10 μm, at least about 20 μm, at least about 50 μm, at least about 100 μm, or at least about 1000 μm.

Further instances relate to chromophores. Any suitable chromophores can be used. Chromophores, in some cases, are adapted to absorb visible light. That means that one or more photons having a wavelength from about 350 nm to about 1000 nm are absorbed by the chromophore to reach one or more excited states. Certain instances provide a chromophore chosen from ruthenium coordination complexes, osmium coordination complexes, copper coordination complexes, porphyrins, phythalocyanines, and organic dyes, and combinations thereof. In some instances, the chromophore is chosen from [Ru(4,4′-(PO₃H₂)₂bpy)₂(bpy)]²⁺, a salt thereof, or a derivative thereof. In other instances, the chromophore is chosen from [Ru(5,5′-divinyl-2,2′-bipyridine)₂(2,2′-bipyridine-4,4′-diylbis(phosphonic acid))]²⁺, a salt thereof, or a derivative thereof. In still other instances, the chromophore has the structure L-A-π-D, a salt thereof, or a derivative thereof, wherein: L is a linking moiety for attaching the chromophore-catalyst assembly to the shell material; A is an electron acceptor; π is a conjugated π-bridge; and D is an electron donor. For example, a chromophore having the structure L-A-π-D is:

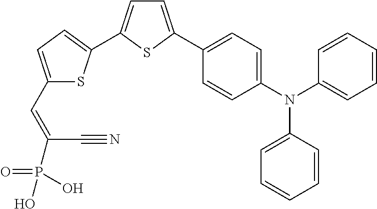 [SMILES: N#C/C(=C\c1ccc(-c2ccc(-c3ccc(N(c4ccccc4)c4ccccc4)cc3)s2)s1)P(=O)(O)O]

a salt thereof, or a derivative thereof. Here, L is the phosphonate linking moiety; A is the cyano group; π is represented by the conjugated thiophene rings and the alkene linkage; and D is the triphenylamine organic dye.

Certain chromophores have at least one linking moiety attaching the chromophore to the shell material. Also, linking moieties attach chromophore-catalyst assemblies to the shell material. Any suitable linking moiety can be used. Phosphonate derivatives such as H₂PO₃ moieties, carboxylate derivatives such as COOH moieties, siloxyl derivatives, β-diketonate derivatives such as acetylacetate moieties, and combinations thereof, may be mentioned as suitable linking moieties. The attachment mechanism includes any suitable mechanism, such as, for example covalent bonding, ionic bonding, or a combination thereof.

Chromophore-catalyst assemblies appear in some embodiments of the present invention. A chromophore-catalyst assembly may be formed by joining at least one chromophore and at least one catalyst by any suitable mechanism, such as, for example, covalent bonding, ionic bonding, and combinations thereof. Among covalent bonding, electropolymerization of vinyl groups on chromophores and catalysts may be mentioned. Among ionic bonding, coordination by linking moieties to metal ions such as Zr⁴⁺ may be mentioned. Any suitable chromophore-catalyst assemblies can be used, alone or in combination. In some cases, a chromophore-catalyst assembly comprises [((PO₃H₂)₂bpy)₂Ru(4-Mebpy-4′-bimpy)Ru(tpy)(OH₂)]⁴⁺, a salt thereof, or a derivative thereof.

As used herein, the following ligands have the indicated structure: bpy indicates 2,2′-bipyridine. (PO₃H₂)₂bpy indicates 4,4′-PO₃H₂-2,2′-bipyridine, sometimes written as 2,2′-bipyridine-4,4′-diylbis(phosphonic acid). 4,4′-((HO)₂OPCH₂)₂bpy adds a methylene link before the phosphonic acid group. 4-Mebpy-4′-bimpy has the structure:

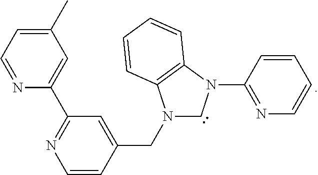

bpm has the structure:

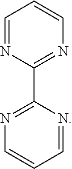 [SMILES: c1cnc(-c2ncccn2)nc1]

bpz has the structure:

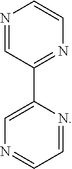 [SMILES: c1cnc(-c2cnccn2)cn1]

Mebim-pz has the structure:

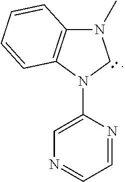

Mebim-py has the structure:

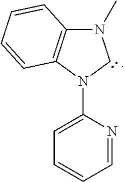

tpy is a tridentate ligand having the structure:

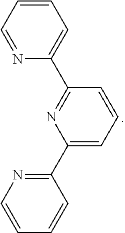 [SMILES: c1ccc(-c2cccc(-c3ccccn3)n2)nc1]

DMAP is a tridentate ligand having the structure:

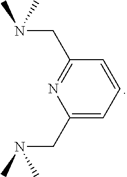

Mebimpy is a tridentate ligand having the structure:

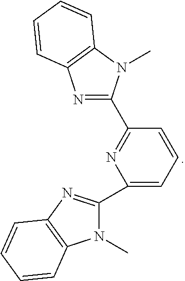 [SMILES: Cn1c(-c2cccc(-c3nc4ccccc4n3C)n2)nc2ccccc21]

Catalysts appear in certain embodiments. Any suitable catalyst can be used. In some cases, the catalyst is chosen from [Ru(tpy)(bpy)(OH₂)]²⁺, [Ru(tpy)(bpm)(OH₂)]²⁺, [Ru(tpy)(bpz)(OH₂)]²⁺, [Ru(tpy)(Mebim-pz)(OH₂)]²⁺, [Ru(tpy)(Mebim-py)(OH₂)]²⁺, [Ru(DMAP)(bpy)(OH₂)]²⁺, [Ru(Mebimpy)(bpy)(OH₂)]²⁺, [Ru(Mebimpy)(Mebim-pz)(OH₂)]²⁺, [Ru(Mebimpy)(Mebimpy)(OH₂)]²⁺, {Ru(Mebimpy)[4,4′-((HO)₂OPCH₂)₂bpyy](OH₂)}²⁺ and Os(tpy)(bpy)(OH₂)²⁺. In other cases, the catalyst has the structure Ru(2,2′-bipyridine-6,6′-dicarboxylate)(R¹)(R²), a salt thereof, or a derivative thereof, wherein R¹ and R² are independently chosen from pyridine, 4-vinylpyridine, pyridin-4-ylmethylphosphonic acid and deprotonated derivatives thereof, and isoquinoline. For example, the catalyst can be Ru((2,2′-bipyridine-6,6′-dicarboxylate)(4-vinylpyridine)₂, a salt thereof, or a derivative thereof. In that example, the catalyst can be electropolymerized with a vinyl-containing chromophore to create a chromophore-catalyst assembly. For another example, wherein the catalyst is Ru((2,2′-bipyridine-6,6′-dicarboxylate)(pyridin-4-ylmethylphosphonic acid)₂, a salt thereof, or a derivative thereof. Still other catalysts include, for example, IrO₂ nanoparticles.

Catalysts may be in electron-transfer communication with chromophores. That means that electron transfer can occur between catalysts and chromophores. Often, this happens when the chromophore absorbs a photon of light, and transfers an electron either to the catalyst or to the core-shell nanoparticles. One or more than one electron may be involved. For example, a chromophore may oxidize catalyst following absorption of a first photon, and then oxidize the catalyst further with the absorption of a second photon.

Catalysts can be adapted to perform at least one chemical reaction. Any suitable chemical reaction can appear. In some cases, water is oxidized. In other cases, carbon dioxide is reduced. In still other cases, electron scavengers or hole scavengers can be reduced or oxidized, respectively. Suitable scavengers include, but are not limited to, hydroquinone and iodide/tri-iodide.

In certain cases, “derivatives” of disclosed molecules can be used. In some cases, a derivative is an ion, such as a mono-deprotonated, di-deprotonated, multi-deprotonated ion of a proton-donating species. In other cases, a derivative is the ionic species left when an ionic salt dissociates in solvent. In still other cases, a derivative is a conjugate acid or a conjugate base. In still other cases, a “derivative” is a substituted species derived from the named compound. The term “substituted” means that the specified group or moiety bears one or more substituents. Where any group may carry multiple substituents, and a variety of possible substituents is provided, the substituents are independently selected, and need not to be the same. The term “unsubstituted” means that the specified group bears no substituents. With reference to substituents, the term “independently” means that when more than one of such substituents are possible, they may be the same or different from each other. In some cases, derivatives are substituted by one or more groups selected from C₁₋₈ alkyl, C₁₋₈ alkenyl, C₁₋₈ alkynyl, aryl, fluoro, chloro, bromo, hydroxyl, C-₁₋₈ alkyloxy, C₁₋₈ alkenyloxy, aryloxy, acyloxy, amino, C₁₋₈ alkylamino, dialkyl(C₁₋₈)amino, arylamino, thio, C₁₋₈ alkylthio, arylthio, cyano, oxo, nitro, acyl, amido, C-₁₋₈ alkylamido, dialkyl(C₁₋₈)amido, carboxyl, or two optional substituents may together with the carbon atoms to which they are attached form a 5- or 6-membered aromatic or non-aromatic ring containing 0, 1 or 2 heteroatoms selected from nitrogen, oxygen or sulphur. Optional substituents may themselves bear additional optional substituents. In certain instances, substituents include C₁₋₃ alkyl such as for example methyl, ethyl, and trifluoromethyl, fluoro, chloro, bromo, hydroxyl, C₁₋₃ alkyloxy such as for example methoxy, ethoxy and trifluoromethoxy, and amino.

“Salts,” as used herein, indicate combinations of cations and anions, and such combinations may or may not also include solvent molecules such as water. Optionally, a salt is neutrally-charged.

Certain instances of the present invention provide at least one overlayer material stabilizing a chromophore or a chromophore-catalyst assembly on the shell material. Any suitable overlayer material can be used. For example the overlayer material may comprise Al₂O₃, TiO₂, or a combination thereof. The overlayer can be added to or formed on the electrode in any suitable manner. In some cases, repeated cycles of atomic layer deposition using appropriate precursor compositions form the desired overlayer material on the electrode, as illustrated in the examples below. The overlayer material can be formed on the electrode in any suitable thickness. In some cases, the overlayer material can be present in a thickness of 1 nm or less, 2 nm or less, 3 nm or less, 4 nm or less, 5 nm or less, 10 nm or less, or 20 nm or less. In other cases, the overlayer material is present in a thickness of about 0.3 nm, or about 0.5 nm. Further cases provide the overlayer material being present in a thickness of about 0.6 nm or about 1.2 nm.

The various components of the present invention can be made in any suitable manner. In some cases, techniques useful for making electrodes, core-shell nanoparticles, chromophores, catalysts, chromophore-catalyst assemblies, overlayers, and cells appear in the literature or are easily derived from known techniques. In addition, several techniques are illustrated in the examples below.

Electrochemical cells, such as dye sensitized photoelectrochemical cells suitable for use in various embodiments of the present invention, can include any suitable components in any suitable configurations. Certain embodiments relate to a photoelectrosynthesis cell, comprising a counter electrode, an electrolyte, and an electrode as described herein. Any suitable counter electrode can be used. For example, platinum, nickel, ceramics, and combinations thereof can be mentioned. Two-electrode or three-electrode configurations can be employed, with the third electrode being any suitable reference electrode. In certain instances, the reference electrode is chosen from standard hydrogen electrode (SHE), normal hydrogen electrode (NHE), silver chloride electrode, saturated calomel electrode (SCE), and saturated sodium calomel electrode (SSCE). Any suitable electrolyte can be used, such as, for example, those exemplified below.

Any useful photochemistry can be performed in certain embodiments of the present invention. Some embodiments relate to methods of splitting water into hydrogen and oxygen, comprising: supplying a photoelectrosynthesis cell as described herein; connecting the electrode with the counter electrode via an external electrical circuit; contacting the electrode and counter electrode with an aqueous electrolyte; and illuminating the electrode with visible light, thereby splitting water. Optionally, any suitable forward bias can be applied across the photoelectrosynthesis cell. The forward bias can be, for example, at least about +0.2 V, at least about +0.4 V, or at least about +0.6 V. Still other embodiments relate to methods of reducing carbon dioxide, comprising: supplying a photoelectrosynthesis cell as claimed in any one of claims 31-34; connecting the electrode with the counter electrode via an external electrical circuit; contacting the electrode and counter electrode with an electrolyte; contacting the electrode with carbon dioxide; and illuminating the electrode with visible light, thereby reducing the carbon dioxide.

### EXAMPLES

### Example 1

### SnO₂/TiO₂|Ruₐ^{II}—Ru_{b}^{II}|(TiO₂ or Al₂O₃) Electrodes and Cells

Here, we report a second generation DSPEC based on a core/shell photoanode. It features both greatly enhanced efficiencies for visible light-driven water splitting and surface stabilization of the assembly by ALD, in some embodiments. Enhanced efficiencies are gained by use of a SnO₂ core in a SnO₂/TiO₂ core/shell structure, in certain instances. SnO₂ has a conduction band potential (E_{CB}) more positive than TiO₂ by ˜0.4 V which creates an internal potential gradient at the SnO₂/TiO₂ interface, inhibiting back electron transfer once injection has occurred. Enhanced stability may be achieved by using ALD to deposit TiO₂ or Al₂O₃ protective overlayers after the assembly is surface-bound to the core/shell, a procedure that has been shown to stabilize surface-bound, phosponate-derivatized chromophores and catalysts toward hydrolysis.

We describe a core/shell nanostructure, derivatized by surface binding of the chromophore-catalyst assembly, [((PO₃H₂)₂bpy)₂Ruₐ(4-Mebpy-4′-bimpy)Ru_{b}(tpy)(OH₂)]⁴⁺ (FIG. 1); —[Ruₐ^{II}—Ru_{b}^{II}—OH₂]⁴⁺(1), to give a photoanode for visible light water splitting in a DSPEC with a Pt cathode for H₂ generation.

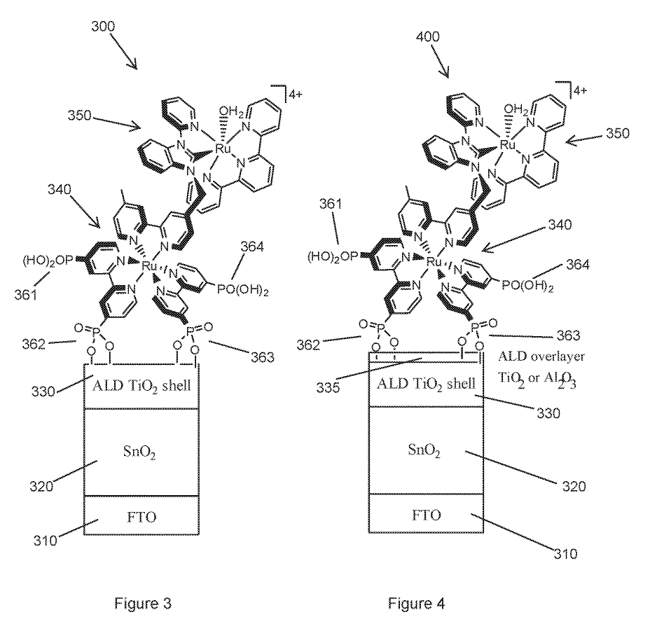

The underlying strategy behind using ALD for both core/shell structure and stabilization of surface binding is shown in FIGS. 3 and 4. Detailed information about the mechanism and rate of water oxidation by the surface-bound assembly is available in a previous publication and the surface photophysical properties of 1 and its singly oxidized form, —[Ruₐ^{II}—Ru_{b}^{II}—OH₂]⁵⁺, on nanoparticle TiO₂ will be reported elsewhere.

FIGS. 3 and 4 schematically depict electrode 300 and electrode 400, respectively, both example embodiments of the present invention. Both electrodes 300, 400 have a core-shell nanoparticle comprising a SnO₂ core material 320 at least partially encompassed by a TiO₂ shell material 330 formed by atomic layer deposition in this case. Core material 320 and shell material 330 together make up the core-shell nanoparticle. Core material 320 is in electron-transfer communication with an electrically conductive substrate, here represented by FTO 310 on a glass support (not shown). Both electrodes 300, 400 further comprise a chromophore 340 and a catalyst 350 that together make up a chromophore-catalyst assembly. Chromophore 340 is adapted to absorb visible light, and catalyst 350 is in electron-transfer communication with the chromophore 340. The chromophore-catalyst assembly further comprises a plurality of linking moieties 361, 362, 363, and 364, which are phosphonic acid groups, some of which 362, 363 are depicted attaching the chromophore-catalyst assembly to the shell material 330. Electrode 400 further comprises at least one overlayer material 335 stabilizing the chromophore-catalyst assembly on the shell material 330. The overlayer material 335 depicted can be, for example, TiO₂ or Al₂O₃.

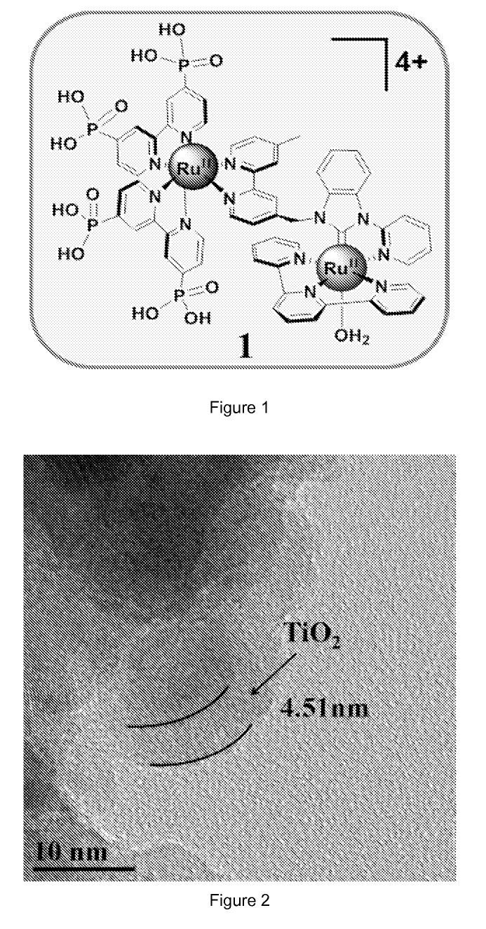

Preparation of the SnO₂ (core)/TiO₂ (shell) structure is described in below. The transmission electron micrograph (TEM) in FIG. 2 illustrates a core/shell structure prepared by uniformly coating a SnO₂ nanoparticle film with 75 ALD cycles of TiO₂. Current-time (i-t) profiles were recorded at the photoanode of a photoelectrochemical cell in 0.5 M LiClO₄ at pH 4.6 with 20 mM acetate/acetic acid buffer or at pH 7 in a 0.1 M phosphate buffer at an ionic strength of 0.5 M with added NaClO₄. The DSPEC cell consisted of a FTO|SnO₂/TiO₂|—[Ruₐ^{II}—Ru_{b}^{II}—OH₂]⁴⁺ core/shell photoanode with a Pt wire as the cathode. It was illuminated at 445 nm (FWHM 20 nm, ˜10 to ˜90 mW/cm², beam diameter 1 cm) by a Lumencor SPECTRA 7-color solid-state light source.

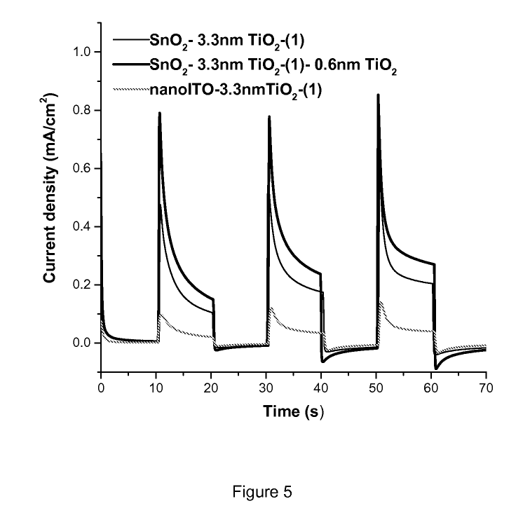

FIG. 5 compares the results of short-term, current density-time DSPEC measurements for nanolTO/TiO₂ and SnO₂/TiO₂ core/shell electrodes with a nominal TiO₂ shell thickness of 3.3 nm. The experiments were carried out in the acetate buffer with added 0.5 M LiClO₄ by applying a voltage bias of 200 mV vs. Ag/AgCl with 445 nm illumination. The performance of these DSPEC water-splitting cells is bias-dependent with an applied bias required to maximize photocurrent and H₂ evolution at the cathode.

From the data in FIG. 5 and the data summary in Table 1, a maximum initial photocurrent density of 0.48 mA/cm² was reached for a SnO₂/TiO₂(3.3 nm) core/shell photoanode. The initial photocurrent increased to 0.79 mA/cm² with a 0.66 nm protective overlayer of TiO₂. The small dark current at the end of the light-on/light-off cycles in FIG. 5 is a characteristic feature of DSPECs. It arises from electron equilibration by back electron transfer through the core/shell network to the oxidized, surface-bound assemblies. It is notable that compared to a nanolTO/TiO₂ core/shell DSPEC under the same conditions, there is a photocurrent increase of ˜5 fold at the onset of the plateau current after 10 seconds of 445 nm illumination.

TABLE 1
Comparisons between SnO₂ and nanoITO as cores with 50 cycle ALD TiO₂ shells
(3.3 nm) derivatized with 1 with a Pt counter electrode at a 200 mV (vs. Ag/AgCl)
bias at pH 4.6 in 0.5M LiClO₄ with 20 mM acetate/acetic acid buffer. The photocurrent
densities in the table are reported in mA cm⁻².

| Light | | | |
|---|---|---|---|
| Intensity | | | SnO₂/TiO₂(3.3 nm)\|- |
| at 445 nm | nanoITO/TiO₂(3.3 nm)\|- | SnO₂/TiO₂(3.3 nm)\|- | [Ruₐ^{II}—Ru_{b}^{II}—OH₂]⁴⁺- |
| (mW cm⁻²) | [Ruₐ^{II}—Ru_{b}^{II}—OH₂]⁴⁺ | [Ruₐ^{II}—Ru_{b}^{II}—OH₂]⁴⁺ | (0.6 nm) TiO₂ |
| 15.1 | 0.10 | 0.48 | 0.79 |
| 55.6 | 0.12 | 0.54 | 0.78 |
| 86.0 | 0.12 | 0.59 | 0.85 |

The influence of variations in TiO₂ shell thickness in the SnO₂/TiO₂ core/shell is summarized in Table 2. These experiments were conducted at pH 7 in a H₂PO₄⁻/HPO₄²⁻ buffer with [HPO₄²⁻] ˜60 mM. The assembly-derivatized core/shell was protected with a 0.55 nm thick overlayer of Al₂O₃. The results in Table 2 show that addition of the TiO₂ shell results in an increase in photocurrent density of >30 with the shell thickness varied from 3.3 to 6.6 nm and a maximum photocurrent reached at 4.5 nm after 75 ALD cycles.

TABLE 2
The effect of TiO₂ shell thickness on photocurrent densities for
FTO|SnO₂/TiO₂|—[Ruₐ^{II}—Ru_{b}^{II}—OH₂]⁴⁺(0.55 nm Al₂O₃) with 445 nm excitation: room
temperature in a H₂PO₄⁻/HPO₄²⁻ buffer ([HPO₄²⁻] ~ 60 mM) with the ionic strength adjusted to
0.5 with NaClO₄ and an external applied bias of 400 mV versus Ag/AgCl. The photocurrent densities in the table are reported in mA/cm².

| Light | | |
|---|---|---|
| intensity | FTO\|SnO₂/TiO₂(3.3 nm)\|- | FTO\|SnO₂/TiO₂(4.5 nm)\|- |
| at 445 nm | [Ruₐ^{II}—Ru_{b}^{II}—OH₂]⁴⁺ | [Ruₐ^{II}—Ru_{b}^{II}—OH₂]⁴⁺ |
| (mW/cm²) | (0.55 nm Al₂O₃) | (no overlayer) |
| 15 | 0.80 | 0.93 |
| 56 | 1.04 | 1.20 |
| 86 | 1.02 | 1.26 |

| Light | | | |
|---|---|---|---|
| intensity | FTO\|SnO₂/TiO₂(4.5 nm)\|- | FTO\|SnO₂/TiO₂(6.6 nm)\|- | FTO\|SnO₂\|- |
| at 445 nm | [Ruₐ^{II}—Ru_{b}^{II}—OH₂]⁴⁺ | [Ruₐ^{II}—Ru_{b}^{II}—OH₂]⁴⁺ | [Ruₐ^{II}—Ru_{b}^{II}—OH₂]⁴⁺ |
| (mW/cm²) | (0.55 nm Al₂O₃) | (0.55 nm Al₂O₃) | (0.55 nm Al₂O₃) |
| 15 | 1.39 | 1.14 | 0.04 |
| 56 | 1.89 | 1.78 | 0.06 |
| 86 | 1.97 | 1.77 | 0.02 |

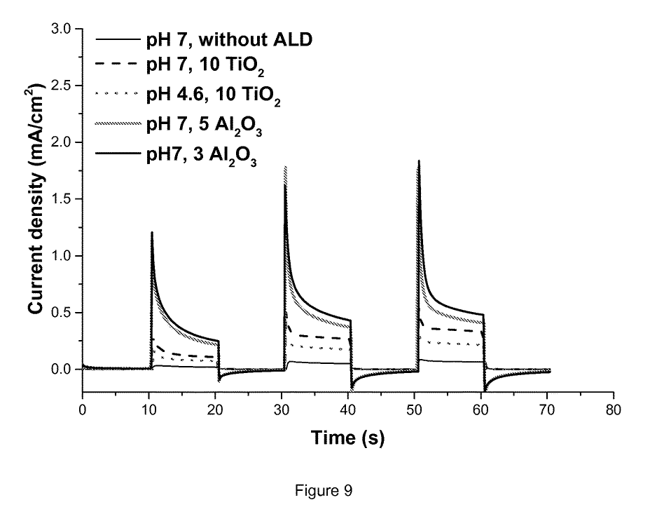

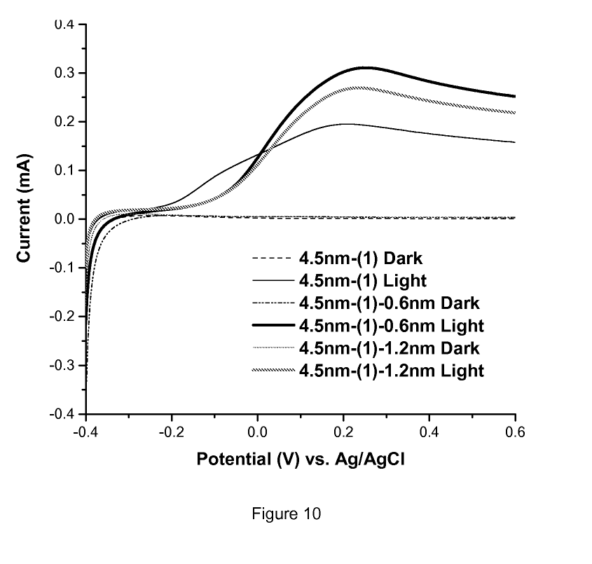

The photocurrent density also depends on the number of ALD overlayer cycles and on the nature of the added overlayer. Based on the photocurrent data at pH 4.6 and pH 7 in Table 3 and FIG. 9, photocurrent efficiencies for the assembly-based photoanodes, FTO|SnO₂/TiO₂(6.6 nm)|—[Ruₐ^{II}—Ru_{b}^{II}—OH₂]⁴⁺(xAl₂O₃ or xTiO₂) were maximized with 0.33 or 0.55 nm overlayers of Al₂O₃ with initial photocurrents reaching 1.97 mA/cm². For TiO₂ overlayers the efficiency was higher at 0.6 nm compared to 1.2 nm. Similar results were obtained for a series of photoanodes with ˜4.5 nm TiO₂ shells. Cyclic voltammograms in the dark and under illumination are shown in FIG. 10.

TABLE 3
Illustrating the role of variations in ALD overlayers on photocurrent
densities for FTO|SnO₂/TiO₂(6.6 nm)|-[Ruₐ^{II}—Ru_{b}^{II}—OH₂]⁴⁺
as a function of incident light intensity and pH. The photocurrent
densities in the table are reported in mA cm⁻² and were recorded
with an applied bias of 400 mV vs. Ag/AgCl.

| Light | | | | | |
|---|---|---|---|---|---|
| intensity, | pH 7^{b} | | | | pH 4.6^{a} |
| 445 nm | No | +0.55 nm | +0.33 nm | +0.6 nm | +0.6 nm |
| (mW cm⁻²) | overlayer | Al₂O₃ | Al₂O₃ | TiO₂ | TiO₂ |
| 15.1 | 0.02 | 1.14 | 1.21 | 0.29 | 0.16 |
| 55.6 | 0.02 | 1.35 | 1.62 | 0.51 | 0.31 |
| 86.0 | 0.04 | 1.77 | 1.83 | 0.59 | 0.37 |

^{a}0.1M LiClO₄ 20 mM in acetic acid/acetate buffer (HAc/OAc⁻).
^{b}0.1M PO₄ buffer with the ionic strength increased to 0.5M with NaClO₄

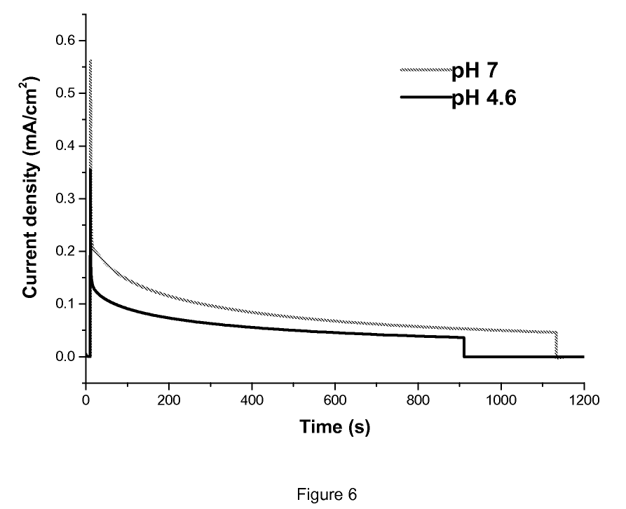

Without an ALD overlayer at pH 4.6 in the acetate buffer, loss of the assembly from the surface by hydrolysis is noticeable after a few minutes of photolysis. At pH 7 in the phosphate buffer, the loss is too rapid for current-time measurements. Loss of the assembly from the surface is inhibited by ALD overlayers of TiO₂ or Al₂O₃. The results of long-term photocurrent measurements on the ALD-stabilized photoanode, FTO|SnO₂/TiO₂(6.6 nm)|—[Ruₐ^{II}—Ru_{b}^{II}—OH₂]⁴⁺(0.6 nmTiO₂), are shown in FIG. 6. The increase in surface stability toward hydrolysis is impressive. A slow decrease in photocurrent with time is observed but it arises from an instability toward ligand loss by the Ru (III) form of the chromophore in the assembly and will be described in a future publication.

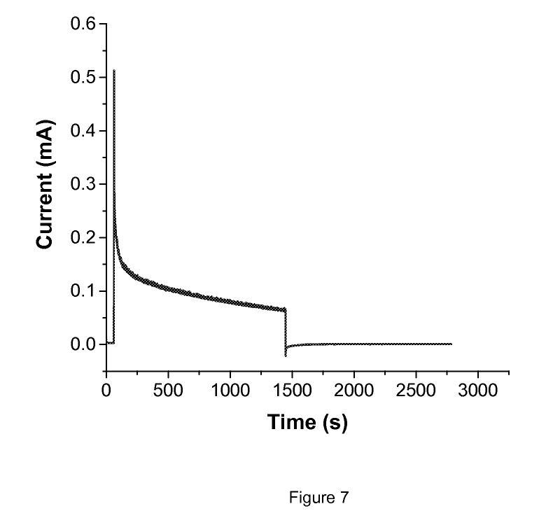

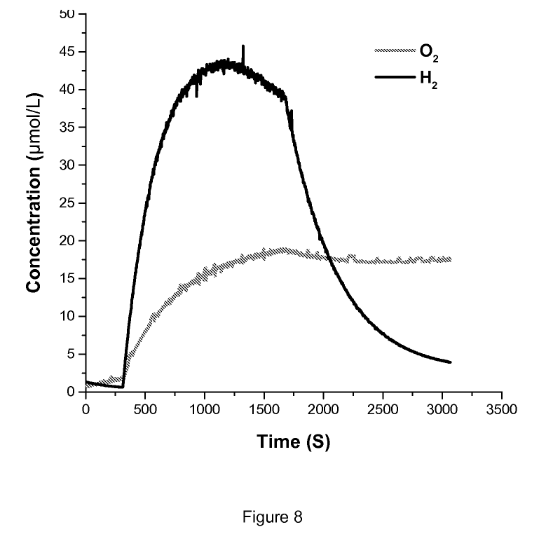

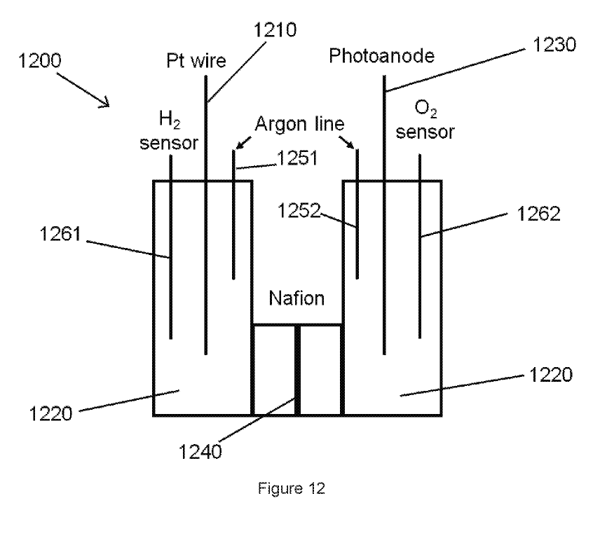

In experiments with assembly 1 on core/shell nanolTO/TiO₂, high Faradaic efficiencies for H₂ production was observed with O₂ evolution confirmed by a rotating ring disc method. In addition, H₂ and O₂ evolution from FTO|SnO₂/TiO₂(4.5 nm)|—[Ruₐ^{II}—Ru_{b}^{II}—OH₂]⁴⁺(0.3 nmAl₂O₃) was confirmed by Clark-type oxygen and hydrogen microsensor measurements (Unisense, Science Park Aarhus, Denmark) with tip diameters of 1.6 mm inserted into the DSPEC cell in 0.1 M H₂PO₄⁻/HPO₄²⁻([HPO₄²⁻] ˜60 mM) at pH 7 with the ionic strength adjusted to 0.5 M with NaClO₄. A schematic illustration of the device is shown in FIG. 12. Current-time plots with 455 nm LED photolysis (46 mW/cm²) and an applied bias of 600 mV are shown in FIG. 7. Current-time curves for the appearance of H₂ and O₂ are shown in FIG. 8. In these measurements, the 600 mV forward bias was applied between the photoanode and Pt cathode in a two electrode configuration. The faradaic efficiencies for H₂ and O₂ measured after 100 seconds of photolysis were 57% and 41%, respectively.

FIG. 12 depicts a photoelectrosynthesis cell 1200 having a platinum wire counter electrode 1210, a working electrode 1230 (comprising the core-shell nanoparticles and a chromophore and a catalyst and/or chromophore-catalyst assembly and optionally an overlayer material)(not shown) and an electrolyte 1220 that contacts both the counter electrode 1210 and the working electrode 1230. This cell 1200 further comprises a Nafion bridge 1240, argon lines 1251, 1252 to de-oxygenate the cell 1200, an H₂ sensor 1261 and an O₂ sensor 1262 to measure the water-splitting progress of the cell 1200.

The results described here present a notable advance for the DSPEC approach to water splitting based on chromophore-catalyst assemblies. Introduction of the SnO₂/TiO₂ core/shell improves cell efficiencies by a factor of ˜5 (see Table 1). Added ALD oxide overlayers stabilize surface binding over extended photolysis periods, even at pH 7 in a phosphate buffer. It is notable that cell efficiencies can be manipulated systematically by varying the core/shell material and its geometry. Under optimal conditions for a FTO|SnO₂/TiO₂(4.5 nm)|—[Ruₐ^{II}—Ru_{b}^{II}—OH₂]⁴⁺(0.3 nmAl₂O₃) photoanode, an initial photocurrent density of 1.97 mA/cm² was reached for 445 nm water splitting. The underlying interfacial dynamics for the integrated molecular assembly-oxide device are currently under investigation by transient absorption and photocurrent measurements in order to assess the kinetic factors required to further increase cell efficiencies.

The results described here are significant in expanding the scope of DSPEC water splitting by manipulating the core/shell structure and utilizing ALD overlayer protection toward hydrolysis.

### Methods:

### Fabrication of Photoelectrodes

Tin Oxide films: The SnO₂ colloidal paste used to prepare electrodes in this study was prepared as follows. In brief, 1 mL acetic acid was added to 30 mL of 15 wt% SnO₂ colloidal dispersion in water (Alfa Aesar) and the mixture was stirred overnight at room temperature. This solution underwent hydrothermal treatment using a Parr Instruments pressure vessel at 240° C. for 60 hours. The resulting solution was then sonicated and 2.5 wt % of both polyethylene oxide (mol. wt. 100,000) and polyethylene glycol (mol. wt. 12,000) was added. Stirring for 12 hours yielded a homogenous colloidal paste. Transparent thin film electrodes were prepared by depositing the sol-gel paste onto conductive FTO glass substrates 4 cm×2.2 cm using the doctor blade method with tape casting and sintered at 450° C. for 30 min under air.

Atomic layer deposition: Atomic layer deposition (ALD) was performed in a commercial reactor (Savannah S200, Cambridge Nanotech, Cambridge, Mass.). Titanium dioxide (TiO₂) was deposited using Tetrakis(dimethylamido)titanium, Ti(NMe₂)₄ (TDMAT, 99.999%, Sigma-Aldrich) and water. The reactor temperature was 130° C. The TDMAT reservoir was kept at 75° C. The TDMAT was pulsed into the reactor for 0.3 s and then held for 10 s before opening the pump valve and purging for 10 s. ALD coating conditions were 130° C. and 20 Torr of N₂ carrier gas with a sequence of 0.3 s metal precursor dose, 10 s hold, 20 s N₂ purge, 0.02 s H₂O dose, 10 s hold, 20 s N₂ purge.

The aluminum oxide (Al₂O₃) was deposited using Trimethylaluminum, Al(CH₃)₃, (TMA, 97%, Sigma-Aldrich). The reactor temperature was 130° C. The TMA reservoir was kept at room temperature. The TMA was pulsed into the reactor for 0.015 s and then held for 10 s before opening the pump valve and purging for 10 s. ALD coating conditions were 130° C. and 20 Torr of N₂ carrier gas with a sequence of 0.15 s metal precursor dose, 10 s hold, 20 s N₂ purge, 0.015 s H₂O dose, 10 s hold, 20 s N₂ purge. The growth rate under these conditions was 0.6 Å per cycles for TiO₂ and 1.1 Å per cycles for Al₂O₃, as determined by ellipsometry on Si wafers. The quality of the TiO₂ outer layers has been confirmed by transmission electron micrograph (TEM) (see FIG. 2).

Photocurrent measurements: The mesoporous films consisting of SnO₂ nanoparticles (diameter of each individual particle ˜10-20 nm) after ALD processing were annealed at 450° C. for 30 min. The assembly was surface-bound to the nanoparticle films by immersing them in assembly solutions 10⁻³-10⁻⁴ M in 0.1 M HNO₃ for ˜16 hours. The overlayers of Al₂O₃ or TiO₂ were deposited by ALD and the slides were used without further annealing.

The fully assembled dye-sensitized photoelectrochemical cell (DSPEC) consisted of a FTO|SnO₂≧TiO₂|—[Ruₐ^{II}—Ru_{b}^{II}—OH₂]⁴⁺ core-shell photoanode, Pt wire cathode, and a Ag/AgCl reference electrode. Current-time (i-t) measurements were recorded with an applied bias vs. Ag/AgCl and and the samples were illuminated with 445 nm light (20 nm FWHM) in both pH 4.6, 0.5 M LiClO₄, 20 mM acetate/acetic acid buffer and 0.1 M phosphate buffer at pH 7 with NaClO₄ supporting electrolyte added to give an ionic strength of 0.5 M. The photocurrent at different intensites of 445 nm (FWHM 20 nm) illumination from 15 to 86 mW cm² were recorded.

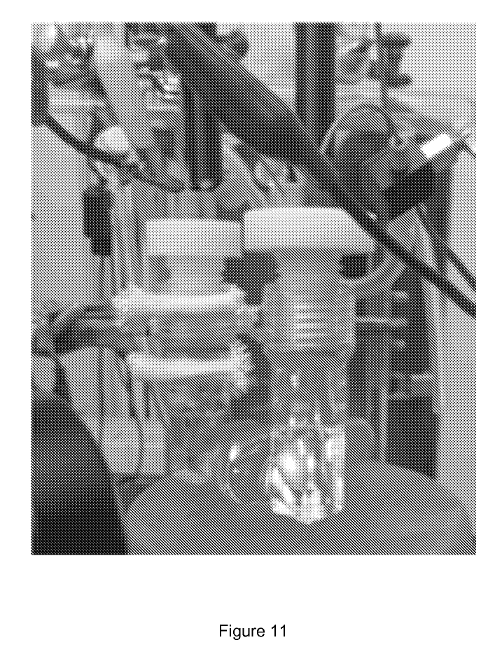

Hydrogen and oxygen evolution: A custom-built, 2-compartment Pyrex cell was used for the electrochemical detection of hydrogen and oxygen. In this approach, the Pt counter electrode and photoanode compartments were separated by a Nafion sheet. The working electrode consisted of a FTO|SnO₂/TiO₂ (6.6 nm)|-[Ruₐ^{II}—Ru_{b}^{II}—OH₂]⁴⁺ electrode. This electrode was prepared with 100 ALD cycles of TiO₂ to form the shell layer as described previously and loaded with the surface-bound assembly 1, and the adsorbed assembly was stabilized on the surface by an additional 10 ALD cycles of Al₂O₃. The setup used for detection of photogenerated oxygen by the chromophore-catalyst assembly 1 is shown in FIG. 11. The photoelectrochemical cell was argon-degassed for 30 minutes prior to photolysis.

### Example 2

### SnO₂/TiO₂|Ru^{II}-vinyl-Ru_{cat}^{II} Electrodes and Cells

This example explores the formation of SnO₂/TiO₂ core-shell nanoparticles, sensitization with a chromophore ([Ru(5,5′-divinyl-2,2′-bipyridine)₂(2,2′-bipyridine-4,4′-diylbis(phosphonic acid))]²⁺) (in this Example, referred to as 1), followed by electropolymerization attachment of a catalyst ([Ru(2,2′-bipyridine-6,6′-dicarboxylic acid)(4-vinylpyridine)₂]) (in this Example, referred to as 2). No overlayer was used in this example.

Core/shell SnO₂/TiO₂ photoanodes were prepared on fluorine-doped tin oxide (FTO) coated glass electrodes. A colloidal SnO₂ paste was synthesized and applied to FTO electrodes by a protocol similar to that described for Example 1. After sintering, the mesoporous SnO₂ layer measured 8 μm thick. As a final step, an overlayer of TiO₂ was deposited on the SnO₂ surface by atomic layer deposition (ALD) using the Ti(IV) precursor TDMAT (tetrakis-(dimethylamido)titanium(IV)) to form 3 nm shells of TiO₂. The core/shell electrodes then underwent annealing at 450° C. in air which reduces both light absorption and light scattering by the TiO₂ shell.

In forming the electro-assembly, the initial step involved the surface binding of 1 by soaking the core/shell electrode in a 400 pM solution of 1 in methanol overnight resulting in monolayer coverage of the SnO₂/TiO₂ surface. In the subsequent vinyl reduction procedure, a pre-derivatized electrode, FTO|nanoSnO₂|TiO₂(3 nm)|-1, was immersed in a 500 μM solution of 2 in acetonitrile 0.1 M in N(n-Bu)₄PF₆. Electro-assembly formation was induced by using a potential step method with the potential at the FTO|nanoSnO₂|TiO₂(3 nm)|-1 electrode held at −2 V vs. Ag⁺/Ag for 1 s followed by a positive step to 0.2 V vs. Ag⁺/Ag for 5 s, over a total of 200 cycles. During the electro-assembly procedure, the solution containing 2 was stirred under a N₂ atmosphere.

Results. For freshly prepared FTO|nanoSnO₂|TiO₂(3 nm)|-1-2 photoanodes, the integrated charge passed at the photoanode during an illumination period was compared with the current measured at the FTO collector electrode resulting from the reduction of photogenerated O₂. After correcting for the collection efficiency of the collector electrode (70%), an average faradaic efficiency of 22% was obtained for the production of O₂ from water over a 5 minute illumination period as an average of five separate, freshly prepared samples.

From the current-time profile at the FTO collector (not shown), a gradual reduction in O₂ evolution occurs following an initial burst upon exposure to light. This pattern parallels the loss in photocurrent during the course of the experiment. At the end of the 15 min illumination period, repetition of the photoelectrochemical experiment results in a steady state photocurrent of 0.15 mA cm⁻² but with negligible O₂ production.

Sustained photocurrents without O₂ production demonstrate a competing anodic process (or processes) for both the electro-assembly in FTO|nanoSnO₂|TiO₂(3 nm)|-1-2 and for FTO|nanoSnO₂|TiO₂(3 nm)|-1. As shown by current-time traces, and by O₂ measurements at the generator-collector electrode, the appearance of a photocurrent under these conditions continues to occur without O₂ evolution. These observations are consistent with light-driven, redox decomposition of the chromophore on the surface following injection and oxidation to −Ru^{III}.

As described here, the electro-assembly procedure provides a new approach to surface assembly preparation avoiding complications arising from the synthesis of pre-formed assemblies. It offers control of surface coverage, an interface stabilized toward desorption, and the facile preparation of layered assembly structures. The impact of the core/shell metal oxide structure on performance in a DSPEC photoanode for water oxidation is significant. The appearance of competitive chromophore decomposition over extended photolysis periods in the 0.1 M H₂PO₄⁻/HPO₄²⁻ buffer at pH 7 highlights the need for either stabilization of the oxidized chromophore or minimization of its residence time in photocatalytic cycles. Stabilization can be enhanced by forming an overlayer material, as described herein, in some embodiments.

### Example 3

### SnO₂/TiO₂|-[L-A-π-D]-Ru(2,2′-bipyridine-6,6′-dicarboxylate)(R¹)(R²) Electrodes and Cells

This example explores electrodes comprising SnO₂/TiO₂ core-shell nanoparticles having an organic dye chromophore and a Ru-centered catalyst. An overlayer material is not used in this example. Within this example, linking moiety L is the phosphonate linking moiety —PO₃H₂, referred to as P. The ligand 2,2′-bipyridine-6,6′-dicarboxylate is referred to as bda in this example.

Experimental. Diethyl cyanomethylphosphonate (98%), trimethylsilyl iodide (97%), trimethylsilyl bromide (97%), piperidine (99%), and all reagents or solvents were obtained from either Sigma-Aldrich or Fisher Scientific and used without any purification. Aqueous solutions were prepared from water purified by a Millipore Milli-Q Synthesis A10 purification system. Deuterated solvent CDCl₃, CD₃OD, and DMSO for NMR were obtained from Cambridge Isotope Laboratories Inc. The ¹H, ¹³C, and ³¹P spectra were recorded on a Bruker 400 spectrometer and all proton and carbon chemical shiftswere measured relative to internal residual chloroform (99.5% CDCl₃) or CD₃OD or DMSO from the lock solvent. The acid protons for P-A-π-D and Ru(bda)(pyP)₂ are not detected by ¹H-NMR.

5′-(4-(Diphenylamino)phenyl)-2,2′-bithiophene-5-carbaldehyde. The aldehyde precursor was synthesized using a previous published method.

(E)-diethyl 1-cyano-2-(5′-(4-(diphenylamino)phenyl)-2,2′-bithiophen-5-yl)vinylphosphonate (OrgD-POEt). A solution of aldehyde precorsor (1.00 g, 2.28 mmol), diethyl cyanomethylphosphonate (0.45 g, 2.51 mmol), and piperidine (0.25 mL, 2.51 mmol) in MeCN (70 ml) was heated to reflux for overnight and cooled to room temperature. The residue was diluted with water and extracted with CH₂Cl₂. The combined organic layer was dried over anhydrous MgSO₄ and filtered off. After removal of the solvent under reduced pressure, silica-gel column chromatography of the residue with CH₂Cl₂ as eluent gave the product OrgD-POEt as a red powder. Yield: 1.01 g (74%). ¹H NMR (CDCl₃): δ8.05 (d, 1H), 7.60 (d, 1H), 7.48 (d, 2H), 7.36 (d, 1H), 7.31, (t, 4H), 7.24 (d, 1H), 7.20 (d, 1H), 7.15 (d, 4H), 7.08 (m, 4H), 4.24 (m, 4H), 1.43 (t, 6H). ¹³C NMR (CDCl₃): δ 150.2, 148.1, 147.2, 146.9, 146.5, 138.3, 135.0, 134.8, 133.8, 129.4, 127.5, 127.0, 126.6, 124.8, 123.7, 123.5, 123.3, 123.1, 116.1. 63.5, 16.3. ³¹P NMR (CDCl₃): δ 512.22. Anal. Found (Calc) for C₃₃H₂₉N₂O₃PS₂: C, 66.52 (66.42); H, 4.95 (4.90); N, 4.73 (4.69).

(E)-1-cyano-2-(5′-(4-(diphenylamino)phenyl)-2,2′-bithiophen-5-yl)vinylphosphonic acid (P-A-π-D). OrgD-POEt (0.6 g, 1.00 mmol) was dissolved in anhydrous CH₂Cl₂ (70 mL) under an atmosphere of argon. To the solution was added trimethylsilyl bromide (0.30 mL, 2.20 mmol), and the reaction was stirred at room temperature under an atmosphere of argon for overnight. The solvent was removed under vacuum, and anhydrous methanol (10 mL) was added. The methanol was removed under vacuum after stirred for 30 min at room temperature. P-A-π-D was purified by silica gel column chromatography using CH₂Cl₂/MeOH (2:1) as the eluent and deep red powder was obtained. Yield: 0.36 g (67%). ¹H NMR (DMSO): δ 7.95 (d, 1H), 7.77 (d, 1H), 7.58 (d, 2H), 7.49-7.25 (m, 7H), 7.11-6.81 (m, 8H). ¹³C NMR (DMSO): δ 147.8, 147.1, 146.5, 146.4, 145.1, 135.7, 130.1, 129.1, 128.1, 127.0, 125.9, 125.0, 124.7, 124.6, 124.1, 124.0 122.9, 122.6, 100.0. ³¹P NMR (DMSO): δ 5.17. Anal. Found (Calc) for C₂₉H₂₁N₂O₃PS₂: C, 64.31 (64.43); H, 3.89 (3.92); N, 5.23 (5.18).

Oxidation catalyst of Ru(bda)(pyPO₃Et₂)₂. The water oxidation catalyst of Ru(bda)(pyP)₂ (bda=2,2′-bipyridine-6,6′-dicarboxylate, pyP=pyridin-4-ylmethylphosphonic acid) was prepared according to previously published procedures. A solution of [Ru(η⁶-benzene)(Cl)₂]₂ (100 mg, 0.19 mmol) and 2,2′-bipyridine-6,6′-dicarboxylate (bda, 95 mg, 0.39 mmol) in distilled MeOH (30 ml) was heated to reflux for 2 h. After cool down to room temperature, diethyl pyridin-4-ylmethylphosphonate (230 mg, 1.00 mmol) and NEt₃ (0.4 ml) was added and then refluxed for overnight. After removal of the solvent under reduced pressure, the residue was diluted with CH₂Cl₂ and then excess hexane was poured to form a precipitate. The precipitate was filtered off and dried under reduced pressure to give a dark black powder. Yield: 120 mg (39%). ¹H NMR (MeOD): δ 8.60 (d, 2H), 8.04 (d, 2H), 7.89 (t, 2H), 7.66 (d, 4H), 7.05 (d, 4H), 4.13 (m, 8H), 3.42 (s, 4H). 1.35 (t, 12H). ³¹P NMR (MeOD): δ 22.22. Anal. Found (Calc) for C₃₂H₃₈N₄O₁₀P₂Ru: C, 47.79 (47.94); H, 4.81 (4.78); N, 6.87 (6.99).

Oxidation catalyst of Ru(bda)(pyP)₂. The Ru(bda)(pyPO₃Et₂)₂ (100 mg, 0.12) was dissolved in CH₂Cl₂ and trimethylsilyl iodide (TMSI, 0.14 ml, 1.00 mmol) was slowly added at room temperature. After overnight, an excess MeOH was added to the mixture and dried under vaccum. The result powder was washed with CH₂Cl₂/hexane (2:1) mixture solvent and dark black powder was obtained. Yield: 43 mg (51%). ¹H NMR (DMSO): δ 9.16 (d, 2H), 8.17 (d, 2H), 8.03 (t, 2H), 7.55 (d, 4H), 7.15 (d, 4H), 3.11 (s, 4H). ³¹P NMR (DMSO): δ 18.17. Anal. Found (Calc) for C₂₄H₂₂N₄O₁₀P₂Ru: C, 41.64 (41.81); H, 3.25 (3.22); N, 8.15 (8.13).

Metal-Oxide Film Preparation. Mesoporous titanium dioxide nanoparticle films (TiO₂, ˜20 nm particle diameter, ˜8 μm thickness for photocurrent experiment or ˜4 μm thickness for CV and TA experiment, 1×1 cm ²) and SnO₂,/(3 nm)TiO₂ core-shell nanoparticle films (SnO₂ core, ˜20 nm particle diameter, ˜8 μm thickness for photocurrent experiment or ˜4 μm thickness for TA experiment, 1×1 cm²) were prepared, according to a procedure similar to that described for Example 1, onto an area of 10 mm×25 mm on top of fluoride-doped tin oxide (FTO)-coated glass electrode (Hartford Glass; sheet resistance 15 Ωcm⁻²). ALD was performed using a Cambridge NanoTech Savannah S200 instrument with TDMAT (tetrakis(dimethylamino)titanium) as Ti precursor for the SnO₂/TiO₂ core-shell electrode. Metal oxide-coated electrodes were derivatized by soaking in 2.0 mM P-A-π-D CH₂Cl₂ solutions overnight followed by neat CH₂Cl₂ soaking for an additional 12 h to remove any loosely bound P-A-π-D. The P-A-π-D undergoes stable surface binding to nanocrystalline, nanoparticle TiO₂ films and other oxides with a maximum surface coverage in a TiO₂ film of Γₘₐₓ=2.4×10⁻⁷ mol cm⁻². Relative surface coverage of P-A-π-D and Ru(bda)(pyP)₂ was controlled by loading times in the two solutions. Surface coverages of each molecule (Γ in mol cm⁻²) were determined from Beer's Law with absorbance measurements at two different wavelengths using the molar absorptivities.

Photophysical and Electrochemical Measurements. Absorption spectra were obtained by placing the dry, derivatized films perpendicular to the detection beam path of the spectrophotometer using an Agilent Cary 60 UV-vis spectrophotometer. The expression, Γ=A(λ)/ε(λ_{480 nm})/1000, was used to calculate surface coverage. Electrochemical measurements (Cyclic Voltammetry, CV) were conducted by using a CH Instruments 660D potentiostat with a Pt-mesh or Pt-wire counter electrode, and an Ag/AgCl (3M KCl, 0.199 V vs. NHE) reference electrode. CV was performed for acetonitrile (ACN) solutions containing 0.1 M TBAP or pH 7 phosphate buffer aqueous solution containing 0.1 M H₂PO₄⁻/HPO₄²⁻, 0.5 M KNO₃ at room temperature under argon.

Nanosecond Transient Absorption Spectroscopy. Transient absorption measurements used a commercially available laser flash photolysis apparatus Edinburgh Instruments, Inc., model LP920) with laser excitation (425 nm, 3.2 mJ, 8-mm diameter, 5-7-ns FWHM) provided by a pulsed neodymiumdoped yttrium aluminum garnet (Spectra-Physics, Inc., model Quanta-Ray LAB-170-10)/optical parametric oscillator (VersaScan-MB) laser combination. The repetition rate of the laser was matched to the rate at which the probe source was pulsed (i.e., intensified 50-fold compared with nonpulsed output), typically 1 Hz, although the laser flashlamps were fired at 10 Hz. Timing of the experiment was PC controlled via Edinburgh software (L900). The white light output of the LP920 probe source, a 450-W Xe lamp, was passed through a 40-nm long-pass color filter before passing through the sample. The LP920 was equipped with a multigrating detection monochromator outfitted with a Hamamatsu R928 photomultiplier tube (PMT) in a noncooled housing and a gated CCD (Princeton Instruments, PI-MAX3). The detector was software selectable with the PMT for monitoring transient absorption kinetics at a single wavelength (10-ns FWHM instrument response function, reliable data out to 400 μs, 300-900 nm) and the gated CCD for transient spectra covering the entire visible region (400-850 nm) at a given time after excitation with a typical gatewidth of 10 ns. For PMT measurements, spectral bandwidth was typically <5 nm with color filters placed after the sample but before the detection monochromator to eliminate laser scatter. Single wavelength kinetic data were collected by averaging 10-100 sequences where one sequence refers to collection of laser-only data followed by pump—probe data. For timescales >10 μs, the probe-only data were also collected within the sequence because the strategy of using the linear portion before excitation to extrapolate the light intensity in the absence of the laser pulse was no longer valid due to a nonlinear temporal output of the pulsed probe source when viewed on longer timescales. Kinetic data were analyzed by using SigmaPlot (Systat, Inc.), Origin (OriginLab, Inc.), or L900 (Edinburgh, Inc.) software. Data were collected at room temperature (22±1° C.).

Generator/collector O₂ detection. The generator/collector experiments for O₂ detection used a four electrode setup along with a bipotentiostat. Two FTO working electrodes in conjunction with a Pt counter and SCE reference electrode were used. One FTO (generator) electrode was prepared as described for the TiO₂ or SnO₂/(3 nm)TiO₂ core/shell photoanodes used in this study; the other FTO (collector) electrode was unmodified. Assembly of the generator/collector setup involved placing the two FTO electrodes with the conductive sides facing with narrow 1 mm thick glass spacers between the lateral edges and sealing the sides with epoxy (Hysol). Prepared in this way, space between the two FTO electrodes will fill with electrolyte by capillary action when the cell is placed in solution. A Thor Labs HPLS 30-04 light source was used to provide white light illumination and a Lumencor Spectra Light Engine LED sources was used for 450 nm illumination. For all indicated experiments using 100 mW cm⁻² white light illumination, the electrochemical cell was positioned an appropriate distance from the light source to receive the indicated light intensity as measured with a photodiode (Newport) and a 400 nm cutoff filter (Newport) was used to prevent direct bandgap excitation of the semiconductor layer. To measure the faradaic efficiency for O₂ production, the charge passed at the generator electrode during the illumination phase of the experiment was compared to the total charge passed at the collector electrode (poised at −0.85 V vs. SCE) during the entire experiment. The faradaic efficiency was corrected for the collection efficiency of the generator/collector setup (70%) that was determined experimentally.

### Results

O₂ production and photocurrents for the assembly electrode, FTO|SnO₂/TiO₂(3 nm)|-[P-A-π-D]-[Ru(bda)(pyP)₂], were observed, with maximum photocurrent levels of 1.4 mA/cm² which decreased over an 10 min interval to 0.1 mA/cm². Introducing hydroquinone into the electrolyte resulted in relatively high efficiency H₂Q oxidation at FTO|SnO₂/TiO₂(3 nm)|-[P-A-π-D]. Although the core/shell structure provides an efficient basis for single photon/single electron activation of the catalyst through the activation sequence, Ru(II) [symbol] Ru(III) [symbol] Ru(IV) [symbol] Ru(V), subsequent water oxidation by Ru(V), is relatively slow. With this interpretation, the origin of the low Faradaic yield for O₂ evolution is slow water oxidation by the catalyst which is in competition with −[P-A-π-D]⁺ decomposition.

Our results are encouraging in demonstrating the use of a D-π-A organic dye as a photosensitizer in a DSPEC photoanode with a high and sustained photocurrent density in an aqueous solution. Photoelectrochemical water oxidation for the co-loaded core/shell assembly, FTO|SnO₂/TiO₂(3 nm)|-[P-A-π-D]-[Ru(bda)(pyP)₂], does occur but, due to slow water oxidation, with a low Faradaic efficiency for O₂ production.

### Example 4

### ITO/TiO₂|RuP₂|TiO₂|IrO₂ NP Electrodes and Cells

In this example, core-shell nanoparticles of ITO cores with TiO₂ shells are formed and dye-sensitized with chromophore [Ru(4,4′-PO₃H₂bpy)₂(bpy)]²⁺(“RuP₂”). An optional TiO₂ overlayer material is added in some cases. A catalyst in the form of IrO₂ nanoparticles is added, and the electrodes are characterized.

Materials. The pH 5.8 buffers that were used in these experiments were composed of 37.5 mM Na₂SiF₆ (Aldrich) and 80 mM NaHCO₃ (Aldrich) in nanopure water. 0.1 M HClO₄ solutions were prepared from concentrated HClO₄ (70%, GFS Chemicals) and nanopure water.

Synthesis of IrOₓ NPs. A 2.5 mM K₂IrCl₆ (Strem Chemicals) solution was adjusted to pH 13 using 50% w/w NaOH (Fisher Scientific). The resulting solution was heated at 90° C. for 20 min and then allowed to cool to RT.

Assembly of RuP₂—IrOₓ NP Systems. RuP₂ was dissolved into a 0.1 M HClO₄ solution, so that the concentration was 0.1 mM RuP₂. The as synthesized IrOₓ NPs were adjusted to pH 1 with 0.1 M HClO₄. The electrodes were first soaked in 0.1 mM solutions of (RuP₂) in 0.1 M HClO₄ for 1.5 h to bind the chromophore followed by a second soaking in a solution of IrOₓ NPs (2.5 mM in Ir) also in 0.1 M HClO₄ for 1.5 h. Coverage of RuP₂ after 1.5 h of soaking is 1×10⁸ mol RuP₂/cm², based off of the geometric area.

Fabrication of NanolTO-FTO Substrates. A 3 g sample of nanoITO (Lihochem, Inc.) powder was added to a mixture of acetic acid (3 g) and ethanol (10 mL), giving a 5 M solution/ suspension (22 wt %). After brief shaking, this mixture was sonicated for 20 min. The colloidal suspension was further sonicated with a Branson ultrasonic horn outfitted with a flat microtip (70% power, 50% duty cycle; 5 min). FTO glass substrates, 4 cm×2.2 cm, were prepared and cleaned by sonication in EtOH for 20 min followed by acetone for 20 min. Kapton tape was applied to one edge to maintain a defined area (1 cm×2.5 cm). The nanolTO colloidal suspension was coated on FTO glass substrates by a spin-coater (600 rpm, 10 s hold). The nanoITO slides were annealed under air and then under 5% H₂. Annealed films were measured to be 3.2±0.5 μm thick by surface profilometry.

ALD Deposition. Atomic layer deposition was performed in a commercial reactor (Savannah S200, Cambridge Nanotech, Cambridge, Mass.). Titanium dioxide (TiO₂) was deposited using (TDMAT, 99.999%, Sigma-Aldrich) and water. The reactor temperature was 130° C. The TDMAT reservoir was kept at 75° C. The TDMAT was pulsed into the reactor for 0.3 s and then held for 10 s before opening the pump valve and purging for 10 s. Standard ALD coating conditions were 130° C. and 20 Torr of N₂ carrier gas with a sequence of 0.3 s metal precursor dose, 10 s hold, 20 s N₂ purge, 0.02 s H₂O dose, 10 s hold, and 20 s N₂ purge. The growth rate under these conditions was 0.6 A per cycles, as determined by ellipsometry on Si wafers. The quality of the outer TiO₂ outer layers with 50 and 100 cycles ALD TiO₂ on nanolTO can be seen by transmission electron micrograph (TEM).

Spectroelectrochemical Characterization. Spectroelectrochemical characterizations were conducted in a three-electrode cell with a 1 cm path length cuvette by using a CHI 670 potentiostat and an Agilent UV-vis spectrometer. The data were analyzed by using SpecFit. The potential was varied in 0.02 V increments from −0.2 to 1.2 V vs Ag/AgCl with spectra recorded at each increment after holding the potential for 60 s (the Ag/AgCl reference is +0.199 V vs NHE).

Photolysis Measurements. Photolysis experiments were conducted in a three-electrode setup, where the working electrode and auxiliary electrodes were separated from the reference electrode via a fine frit. A Lumencor LED was used to back-illuminate the working electrode at a 45° angle at 455 nm at different intensities. The current change was monitored using a CHI 670 potentiostat. The difference in current from when the light was off and on was determined to be the photocurrent.

O₂ Detection. O₂ was detected using a four-electrode setup, where the two working electrodes were attached to each other in a thin cell-like arrangement via epoxy. The two working electrodes were spaced 1 mm apart using glass spacers. Working electrode 1 (WE1) was a nanolTO/TiO₂ core/shell electrode on FTO with the RuP₂—IrOₓ NP assembly; working electrode 2 (WE2) was an FTO electrode. Pt wire and Ag/AgCI were used for the auxiliary and reference electrodes, respectively. Light was shown from the back of WE1 while a potential of 400 mV vs Ag/AgCl was held at that same electrode. The potential at WE2 was held at −900 mV vs Ag/AgCl in order to measure the reduction of O₂ produced at WE1.

### Results.

TABLE 4
Photocurrent (μA/cm²) of the RuP₂—IrO_{X} NP
Assemblies on Three Different Electrodes in pH 5.8 NaSiF₆ Solution,
Illuminated at 450 nm at 14.5 mW/cm² with an Applied
Potential Bias of 0 V vs Ag/AgCl^{a}

| | | nanoITO/TiO₂ core- | nanoITO/TiO₂ core- |
|---|---|---|---|
| | TiO₂ | shell, 50 cycles | shell, 100 cycles |
| IrO_{X} NPs | 0.27 | 22 | 37 |
| RuP₂ | 6.9 | 53 | 27 |
| RuP₂ + IrO_{X} NPs | 37 | 88 | 100 |

^{a}50 cycles and 100 cycles refer to 3.7 and 6.6 nm thickness of the TiO₂ shell.

The effect of an added 10 cycle TiO₂ overlayer (less than 1 nm in thickness) added to stabilize —RuP₂ before addition of the IrOₓ NPs is remarkable. After 2 h of photolysis with a 300 mV applied bias vs Ag/AgCl, the photocurrent from the unstabilized assembly fell appreciably, to a level (97 μA/cm²) that is below the photocurrent of the electrode with the overlayer protection. The stabilized electrode having a TiO₂ overlayer sustains a photocurrent of 110 μA/cm² over the photolysis period, indicating significant improvement in stability.

### REFERENCES

1 Concepcion, J. J., House, R. L., Papanikolas, J. M. & Meyer, T. J. Chemical approaches to artificial photosynthesis. Proc. Natl. Acad. Sci. 109, 15560-15564 (2012).
2 Alstrum-Acevedo, J. H., Brennaman, M. K. & Meyer, T. J. Chemical approaches to artificial photosynthesis. 2. Inog. Chem. 44, 6802 (2005).
3 Walter, M. G. et al. Solar Water Splitting Cells. Chem. Rev. 110, 6446-6473 (2010).
4 Lewis, N. S. & Nocera, D. G. Powering the planet: Chemical challenges in solar energy utilization. Proc. Natl. Acad. Sci. 103, 15729-15735 (2006).
5 Faunce, T. A. et al. Energy and environment policy case for a global project on artificial photosynthesis. Energy & Environ. Sci. 6, 695-698 (2013).
6 Alibabaei, L. et al. Applications of metal oxide materials in dye sensitized photoelectrosynthesis cells for making solar fuels: Let the molecules do the work. J Mater Chem A 1, 4133-4145 (2013).
7 Treadway, J. A., Moss, J. A. & Meyer, T. J. Visible Region Photooxidation on TiO2 with a Chromophore-Catalyst Molecular Assembly.. lnorg. Chem. 38, 4386-4387 (1999).
8 Song, W., Chen, Z., Brennaman, M. K., Concepcion, J. & Meyer, T. J. Making Solar Fuels by Artificial Photosynthesis. . Pure and Appl. Chem 83, 749-768 (2011).
9 Ding, X. et al. Visible Light-Driven Water Splitting in Photoelectrochemical Cells with Supramolecular Catalysts on Photoanodes. ACS Catalysis 4, 2347-2350 (2014).
10 Williams, V. O. et al. Fast Transporting ZnO—TiO2 Coaxial Photoanodes for Dye-Sensitized Solar Cells Based on ALD-Modified SiO2 Aerogel Frameworks. ACS Nano 6, 6185-6196 (2012).
11 Martinson, A. B. F. et al. Radial Electron Collection in Dye-Sensitized Solar Cells. Nano Lett. 8, 2862-2866 (2008).
12 Park, K. et al. Effect of an Ultrathin TiO2 Layer Coated on Submicrometer-Sized ZnO Nanocrystallite Aggregates by Atomic Layer Deposition on the Performance of Dye-Sensitized Solar Cells. Advanced Materials 22, 2329-2332 (2010).
13 Song, W. et al. Visible Light Driven Benzyl Alcohol Dehydrogenation in a Dye-Sensitized Photoelectrosynthesis Cell. Journal of the American Chemical Society 136, 9773-9779 (2014).
14 Alibabaei, L. et al. Atomic Layer Deposition of TiO2 on Mesoporous nanoITO: Conductive Core-Shell Photoanodes for Dye-Sensitized Solar Cells. Nano Letters 14, 3255-3261 (2014).
15 Chandiran, A. K. et al. Low-Temperature Crystalline Titanium Dioxide by Atomic Layer Deposition for Dye-Sensitized Solar Cells. ACS Applied Materials & Interfaces 5, 3487-3493. (2013).
16 Alibabaei, L. et al. Solar water splitting in a molecular photoelectrochemical cell. Proceedings of the National Academy of Sciences 110, 20008-20013 (2013).
17 Moore, G. F. et al. A visible light water-splitting cell with a photoanode formed by codeposition of a high-potential porphyrin and an iridium water-oxidation catalyst. Energy & Environ. Sci. 4, 2389-2392 (2011).
18 Lv, H. et al. Polyoxometalate water oxidation catalysts and the production of green fuel. Chem. Soc. Rev. 41, 7572-7589 (2012).
19 Gao, Y. et al. Visible Light Driven Water Splitting in a Molecular Device with Unprecedentedly High Photocurrent Density. J. Am. Chem. Soc. 135, 4219-4222 (2013).
20 Brimblecombe, R., Koo, A., Dismukes, G. C., Swiegers, G. F. & Spiccia, L. Solar driven water oxidation by a bioinspired manganese molecular catalyst. J. Am.Chem. Soc. 132, 2892-2894 (2010).
21 Youngblood, W. J. et al. J. Am. Chem. Soc. 131, 926 (2009).
22 Chen, Z. et al. Concerted 0 Atom-Proton Transfer in the O—O Bond Forming Step of Water Oxidation;. Proc. Nat. Acad. Sci. 107, 7225-7229 (2010).
23 Vannucci, A. K. et al. Crossing the divide between homogeneous and heterogeneous catalysis in water oxidation. Proceedings of the National Academy of Sciences 110, 20918-20922 (2013).
24 Tamaki, Y., Vannucci, A., Dares, C., Binstead, R. & Meyer, T. J. One-electron Activation of Water Oxidation Catalysis. J. Am. Chem. Soc. 136, 6854-6857 (2014).
25 Hanson, K. et al. Stabilization of [Ru(bpy)2(4,4′-(P03H2)bpy)]2+on Mesoporous TiO2 with Atomic Layer Deposition of Al2O3. Chemistry of Materials 25, 3-5 (2013).
26 Hanson, K., Losego, M. D., Kalanyan, B., Parsons, G. N. & Meyer, T. J. Stabilizing Small Molecules on Metal Oxide Surfaces Using Atomic Layer Deposition. Nano Letters 13, 4802-4809 (2013).
27 Norris, M. R., Concepcion, J. J., Fang, Z., Templeton, J. L. & Meyer, T. J. Low overpotential water oxidation by a surface-bound Ruthenium-chromophore-Ruthenium-catalyst assembly. Angewandte Chemie International Edition 52, 13580-13583 (2013).
28 Brennaman, M. K. et al. The Roles of Injection and Cross-Surface Dynamics in a Ruthenium-Based Chromophore-Catalyst Assembly on TiO2. JACS (2014, Submitted).
29. Harrison, D. P. ,Alibabaei, L. Kenneth G. Hanson, K. Michael R. Norris, M. Aaron K. Vannucci, A. & Thomas J. Meyer T. J. Instability of Phosphonate-Derivatized, RuIII Polypyridyl Complexes on Metal Oxide Surfaces. manuscript in preparation.(2014)
30. Chappel, S. & Zaban, A. Nanoporous SnO₂ electrodes for dye-sensitized solar cells: improved cell performance by the synthesis of 18 nm SnO₂ colloids. Solar Energy Materials a Solar Cells 71, 141-152 (2002).

### INDUSTRIAL APPLICABILITY

Certain embodiments of the present invention can be useful in the industrial performance of useful chemistry. Using either natural or artificial light, water can be split into hydrogen and oxygen, for example; carbon dioxide can be reduced to fuel or precursor molecules, for another example; and other useful chemistries can be catalyzed, in other examples. Further industrial applications can be discerned from the claims and the disclosure.

### Embodiments

Embodiment 1. An electrode comprising:
at least one core-shell nanoparticle, comprising:

a core material at least partially encompassed by a shell material.

Embodiment 2. The electrode of embodiment 1, further comprising: at least one chromophore-catalyst assembly, comprising:

a chromophore adapted to absorb visible light;
a catalyst in electron-transfer communication with the chromophore, and adapted to perform at least one chemical reaction; and
at least one linking moiety attaching the chromophore-catalyst assembly to the shell material.

Embodiment 3. The electrode of embodiment 2, further comprising: at least one overlayer material stabilizing the chromophore-catalyst assembly on the shell material.

Embodiment 4. The electrode of any one of embodiments 1-3, wherein the core material is in electron-transfer communication with an electrically-conductive substrate.

Embodiment 5. The electrode of any one of embodiments 1-4, wherein the core material is a semiconductor metal oxide.

Embodiment 6. The electrode of any one of embodiments 1-5, wherein the core material has a core material conduction band potential that is more positive than the shell material's conduction band potential.

Embodiment 7. The electrode of embodiment 6, wherein the core material conduction band potential is at least about 0.2 V more positive than the shell material's conduction band potential.

Embodiment 8. The electrode of embodiment 6, wherein the core material conduction band potential is at least about 0.3 V more positive than the shell material's conduction band potential.

Embodiment 9. The electrode of embodiment 6, wherein the core material conduction band potential is at least about 0.4 V more positive than the shell material's conduction band potential.

Embodiment 10. The electrode of any one of embodiments 1-9, wherein the core material comprises SnO₂.

Embodiment 11. The electrode of any one of embodiments 1-10, wherein the shell material comprises TiO₂, Al₂O₃, ZnO, or a combination thereof.

Embodiment 12. The electrode of any one of embodiments 2-11, wherein the chromophore-catalyst assembly comprises [((PO₃H₂)₂bpy)₂Ru(4-Mebpy-4′-bimpy)Ru(tpy)(OH₂)]⁴⁺, a salt thereof, or a derivative thereof.

Embodiment 13. The electrode of any one of embodiments 2-11, wherein the chromophore is chosen from ruthenium coordination complexes, osmium coordination complexes, copper coordination complexes, porphyrins, phythalocyanines, and organic dyes, and combinations thereof.

Embodiment 14. The electrode of any one of embodiments 2-11, wherein the chromophore is chosen from [Ru(4,4′-(PO₃H₂)₂bpy)₂(bpy)]²⁺, a salt thereof, or a derivative thereof.

Embodiment 15. The electrode of any one of embodiments 2-11, wherein the chromophore is chosen from [Ru(5,5′-divinyl-2,2′-bipyridine)₂(2,2′-bipyridine-4,4′-diylbis(phosphonic acid))]²⁺, a salt thereof, or a derivative thereof.

Embodiment 16. The electrode of any one of embodiments 2-11, wherein the chromophore has the structure L-A-π-D, a salt thereof, or a derivative thereof, wherein:
L is a linking moiety for attaching the chromophore-catalyst assembly to the shell material;
A is an electron acceptor;
π is a conjugated π-bridge; and
D is an electron donor.

Embodiment 17. The electrode of embodiment 16, wherein the chromophore having the structure L-A-π-D is:

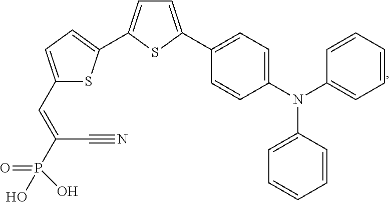 [SMILES: N#C/C(=C\c1ccc(-c2ccc(-c3ccc(N(c4ccccc4)c4ccccc4)cc3)s2)s1)P(=O)(O)O]

a salt thereof, or a derivative thereof.

Embodiment 18. The electrode of any one of embodiments 2-17, wherein the catalyst is chosen from [Ru(tpy)(bpy)(OH₂)]²⁺, [Ru(tpy)(bpm)(OH₂)]²⁺, [Ru(tpy)(bpz)(OH₂)]²⁺, [Ru(tpy)(Mebim-pz)(OH₂)]²⁺, [Ru(tpy)(Mebim-py)(OH₂)]²⁺, [Ru(DMAP)(bpy)(OH₂)]²⁺, [Ru(Mebimpy)(bpy)(OH₂)]²⁺, [Ru(Mebimpy)(Mebim-pz)(OH₂)]²⁺, [Ru(Mebimpy)(Mebimpy)(OH₂)]²⁺, {Ru(Mebimpy)[4,4′-((HO)₂OPCH₂)₂bpy](OH₂)}²⁺ and Os(tpy)(bpy)(OH₂)²⁺.

Embodiment 19. The electrode of any one of embodiments 2-17, wherein the catalyst has the structure Ru(2,2′-bipyridine-6,6′-dicarboxylate)(R¹)(R²), a salt thereof, or a derivative thereof, wherein R¹ and R² are independently chosen from pyridine, 4-vinylpyridine, pyridin-4-ylmethylphosphonic acid and deprotonated derivatives thereof, and isoquinoline.

Embodiment 20. The electrode of embodiment 19, wherein the catalyst is Ru((2,2′-bipyridine-6,6′-dicarboxylate)(4-vinylpyridine)₂, a salt thereof, or a derivative thereof.

Embodiment 21. The electrode of embodiment 19, wherein the catalyst is Ru((2,2′-bipyridine-6,6′-dicarboxylate)(pyridin-4-ylmethylphosphonic acid)₂, a salt thereof, or a derivative thereof.

Embodiment 22. The electrode of any one of embodiments 3-21, wherein the overlayer material comprises Al₂O₃.

Embodiment 23. The electrode of any one of embodiments 3-22, wherein the overlayer material comprises TiO₂.

Embodiment 24. The electrode of any one of embodiments 4-23, wherein the electrically-conductive substrate comprises a conductive metal oxide.

Embodiment 25. The electrode of embodiment 24, wherein the conductive metal oxide comprises tin-doped indium oxide (ITO), fluorine-doped tin oxide (FTO), antimony tin oxide (ATO), gallium zinc oxide (GZO), indium zinc oxide (IZO), copper aluminum oxide, fluorine-doped zinc oxide, aluminum zinc oxide (AZO), or a combination of two or more thereof.

Embodiment 26. The electrode of any one of embodiments 1-25, wherein the core material comprises tin-doped indium oxide (ITO), fluorine doped tin oxide (FTO), antimony tin oxide (ATO), gallium zinc oxide (GZO), indium zinc oxide (IZO), copper aluminum oxide (CAO), fluorine doped zinc oxide (FZO), aluminum zinc oxide (AZO), SnO₂, ZrO₂, TiO₂, Al₂O₃, SiO₂, or a combination of two or more thereof.

Embodiment 27. The electrode of embodiment 1 further comprising: at least one chromophore adapted to absorb visible light, having at least one linking moiety attaching the chromophore to the shell material.

Embodiment 28. The electrode of embodiment 27, further comprising at least one overlayer material stabilizing the chromophore on the shell material.

Embodiment 29. The electrode of any one of embodiments 27-28, further comprising at least one catalyst in electron-transfer communication with the chromophore, and adapted to perform at least one chemical reaction.

Embodiment 30. The electrode of embodiment 29, wherein the at least one catalyst comprises IrO₂ nanoparticles.

Embodiment 31. A photoelectrosynthesis cell, comprising: a counter electrode; an electrolyte; and the electrode of any one of embodiments 1-30.

Embodiment 32. The photoelectrosynthesis cell of embodiment 31, wherein the counter electrode comprises platinum.

Embodiment 33. The photoelectrosynthesis cell of any one of embodiments 31-32, further comprising a reference electrode.

Embodiment 34. The photoelectrosynthesis cell of embodiment 33, wherein the reference electrode is chosen from standard hydrogen electrode (SHE), normal hydrogen electrode (NHE), silver chloride electrode, saturated calomel electrode (SCE), and saturated sodium calomel electrode (SSCE).

Embodiment 35. A method of splitting water into hydrogen and oxygen, comprising:
supplying a photoelectrosynthesis cell as claimed in any one of embodiments 31-34;
connecting the electrode with the counter electrode via an external electrical circuit;
contacting the electrode and counter electrode with an aqueous electrolyte;
and illuminating the electrode with visible light, thereby splitting water.

Embodiment 36. The method of embodiment 35, further comprising: applying a forward bias across the photoelectrosynthesis cell.

Embodiment 37. The method of embodiment 36, wherein the forward bias is at least +0.2 V.

Embodiment 38. The method of embodiment 36, wherein the forward bias is at least +0.4 V.

Embodiment 39. The method of embodiment 36, wherein the forward bias is at least +0.6 V.

Embodiment 40. A method of reducing carbon dioxide, comprising: supplying a photoelectrosynthesis cell as claimed in any one of embodiments 31-34; connecting the electrode with the counter electrode via an external electrical circuit; contacting the electrode and counter electrode with an electrolyte; contacting the electrode with carbon dioxide; and illuminating the electrode with visible light, thereby reducing the carbon dioxide.

As previously stated, detailed embodiments of the present invention are disclosed herein; however, it is to be understood that the disclosed embodiments are merely exemplary of the invention that may be embodied in various forms. It will be appreciated that many modifications and other variations stand within the intended scope of this invention as claimed below. Furthermore, the foregoing description of various embodiments does not necessarily imply exclusion. For example, “some” embodiments may include all or part of “other” and “further” embodiments within the scope of this invention. In addition, “a” does not mean “one and only one;” “a” can mean “one and more than one.”

1. An electrode comprising:
at least one core-shell nanoparticle, comprising:
a core material at least partially encompassed by a shell material; at least one chromophore-catalyst assembly, comprising:
a chromophore adapted to absorb visible light;
a catalyst in electron-transfer communication with the chromophore, and adapted to perform at least one chemical reaction; and
at least one linking moiety attaching the chromophore-catalyst assembly to the shell material; and
at least one overlayer material stabilizing the chromophore-catalyst assembly on the shell material; and
wherein the core material is in electron-transfer communication with an electrically-conductive substrate.

2.-4. (canceled)

5. The electrode of claim 1, wherein the core material is a semiconductor metal oxide.

6. The electrode of claim 1, wherein the core material has a core material conduction band potential that is more positive than the shell material's conduction band potential.

7. The electrode of claim 6, wherein the core material conduction band potential is at least about 0.2 V more positive than the shell material's conduction band potential.

8. The electrode of claim 6, wherein the core material conduction band potential is at least about 0.3 V more positive than the shell material's conduction band potential.

9. The electrode of claim 6, wherein the core material conduction band potential is at least about 0.4 V more positive than the shell material's conduction band potential.

10. The electrode of claim 1, wherein the core material comprises SnO₂.

11. The electrode of claim 1, wherein the shell material comprises TiO₂, Al₂O₃, ZnO, or a combination thereof.

12. The electrode of claim 1, wherein the chromophore-catalyst assembly comprises [(((PO₃H₂)₂bpy)₂Ru(4-Mebpy-4′-bimpy)Ru(tpy)(OH₂)]⁴⁺, a salt thereof, or a derivative thereof.

13. The electrode of claim 1, wherein the chromophore is chosen from ruthenium coordination complexes, osmium coordination complexes, copper coordination complexes, porphyrins, phythalocyanines, and organic dyes, and combinations thereof.

14. The electrode of claim 1, wherein the chromophore is chosen from [Ru(4,4′-(PO₃H₂)₂bpy)₂(bpy)]²⁺, a salt thereof, or a derivative thereof.

15. The electrode of claim 1, wherein the chromophore is chosen from [Ru(5,5′-divinyl-2,2′-bipyridine)₂(2,2′-bipyridine-4,4′-diylbis(phosphonic acid))]²⁺, a salt thereof, or a derivative thereof.

16. The electrode of claim 1, wherein the chromophore has the structure L-A-π-D, a salt thereof, or a derivative thereof,
wherein:
L is a linking moiety for attaching the chromophore-catalyst assembly to the shell material;
A is an electron acceptor;
π is a conjugated π-bridge; and
D is an electron donor.

17. The electrode of claim 16, wherein the chromophore having the structure
L-A-π-D is: 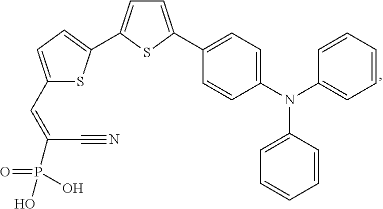 [SMILES: N#C/C(=C\c1ccc(-c2ccc(-c3ccc(N(c4ccccc4)c4ccccc4)cc3)s2)s1)P(=O)(O)O]
a salt thereof, or a derivative thereof.

18. The electrode of claim 1, wherein the catalyst is chosen from [Ru(tpy)(bpy)(OH₂)]²⁺, [Ru(tpy)(bpm)(OH₂)]²⁺, [Ru(tpy)(bpz)(OH₂)]²⁺, [Ru(tpy)(Mebim-pz)(OH₂)]²⁺, [Ru(tpy)(Mebim-py)(OH₂)]²⁺, [Ru(DMAP)(bpy)(OH₂)]²⁺, [Ru(Mebimpy)(bpy)(OH₂)]²⁺, [Ru(Mebimpy)(Mebim-pz)(OH₂)]²⁺, [Ru(Mebimpy)(Mebimpy)(OH₂)]²⁺, {Ru(Mebimpy)[4,4′-((HO)₂OPCH₂)₂bpy](OH₂)}²⁺ and Os(tpy)(bpy)(OH₂)²⁺.

19. The electrode of claim 1, wherein the catalyst has the structure Ru(2,2′-bipyridine-6,6′-dicarboxylate)(R¹)(R²), a salt thereof, or a derivative thereof, wherein R¹ and R² are independently chosen from pyridine, 4-vinylpyridine, pyridin-4-ylmethylphosphonic acid and deprotonated derivatives thereof, and isoquinoline.

20. The electrode of claim 19, wherein the catalyst is Ru((2,2′-bipyridine-6,6′-dicarboxylate)(4-vinylpyridine)₂, a salt thereof, or a derivative thereof.

21. The electrode of claim 19, wherein the catalyst is Ru((2,2′-bipyridine-6,6′-dicarboxylate)(pyridin-4-ylmethylphosphonic acid)₂, a salt thereof, or a derivative thereof.

22. The electrode of claim 1, wherein the overlayer material comprises Al₂O₃.

23. The electrode of claim 1, wherein the overlayer material comprises TiO₂.

24.-40. (canceled)
